(19) United States
(12) Patent Application Publication
(10) Pub. No.: US 2020/0251460 A1
(43) Pub. Date: Aug. 6, 2020

(54) MICRO-LED ELEMENT, IMAGE DISPLAY ELEMENT, AND PRODUCTION METHOD

(71) Applicant: SHARP KABUSHIKI KAISHA, Sakai City, Osaka (JP)

(72) Inventor: KATSUJI IGUCHI, Sakai City, Osaka (JP)

(21) Appl. No.: 16/641,907

(22) PCT Filed: Mar. 6, 2018
(86) PCT No.: PCT/JP2018/008583

§ 371 Date: Feb. 25, 2020

(30) Foreign Application Priority Data
Aug. 25, 2017 (JP) 2017-162485

(51) Int. Cl. H01L 25/16; H01L 33/32; H01L 33/38; H01L 33/24; H01L 33/44; H01L 33/60; H01L 33/52; H01L 33/00; H01L 33/62

(52) U.S. Cl. CPC H01L 25/167; H01L 33/32; H01L 33/382; H01L 33/24; H01L 2933/0016; H01L 33/60; H01L 33/52; H01L 33/0093; H01L 33/62; H01L 33/44

(57) ABSTRACT

A micro-LED element includes a nitride semiconductor layer in which an N-type layer, a light-emitting layer, and a P-type layer are stacked in this order when viewed from a light emission surface side; and a P-side electrode layer formed on the P-type layer side. The N-type layer includes a first region in contact with the light-emitting layer and a second region including the light emission surface. An angle between a first interface surrounding at least a side of the first region in the nitride semiconductor layer and the light-emitting layer is a prescribed first angle at which light propagating in a direction along the light-emitting layer is reflected in a direction toward the light emission surface. An angle between a second interface surrounding a side of the second region in the nitride semiconductor layer and the light-emitting layer is a prescribed second angle larger than the first angle.

### TECHNICAL FIELD

The present invention relates to a micro-LED element being a fine LED element and a production method of the micro-LED element. The present invention also relates to an image display element including a plurality of such micro-LED elements.

### BACKGROUND ART

In the field of flat panel displays, liquid crystal display elements are widely used as display elements regardless of the size of the display, from large to small. The liquid crystal display element adjusts luminance of each pixel by turning on and off backlight by a liquid crystal element.

A liquid crystal display using a liquid crystal display element as a display element has a problem that it is difficult to increase contrast. This is because, even in a case where the liquid crystal display element is controlled such that the backlight is turned off, it is difficult for the liquid crystal display element to completely block the backlight.

The liquid crystal display has a problem that it is difficult to improve color rendering properties. The reason is as follows. It is difficult for a plurality of color filters (for example, three colors of RGB) used for expressing each primary color to completely block light other than a transmission band. As a result, it is not possible for each color filter to completely separate light in the transmission band.

An organic EL display employing an organic EL element as a display element has been put to practical use. The organic EL element is a self-luminous element and is a monochromatic light emitting element for each of R, G, and B. Thus, the organic EL display is expected to be able to solve the above-described problems of the liquid crystal display, such as the contrast and the color rendering properties, and has been practically used in the field of small flat panel displays for smartphones.

However, the organic EL display has a problem that the luminance of the organic EL element is easily deteriorated with time. This is because a light-emitting layer of the organic EL element is made of an organic substance. Therefore, organic EL displays are used in smartphones that have a relatively short product life (in other words, a short replacement cycle), but it is difficult to employ the organic EL displays for products (for example, televisions) with a long product life (in other words, a long replacement cycle). In addition, in a case where the organic EL display is used for a product having a long product life, a complicated circuit for compensating for the deterioration of luminance with time is required.

As a flat panel display that solves the problems of the liquid crystal display and the organic EL display as described above, an LED display employing a compound semiconductor LED element as a display element has been proposed (see PTLs 1 and 2). The LED display is configured by arranging compound semiconductor LED elements in a two-dimensional array, and has high contrast, excellent color rendering properties, and luminance which is hard to be deteriorated with time.

In particular, LED elements have high light emission efficiency and high long-term reliability (there is little deterioration in luminance with time), in comparison to organic EL elements. Thus, the LED display can realize a high-luminance display that is easy to see even outdoors. In the field of ultra-large flat panel displays, LED displays have begun to be used for digital signage. LED displays are also being developed in the field of small to large flat panel displays such as wearable terminals and TVs.

Such an LED element is called a micro-LED element. At the research and development level, miniaturization of micro-LED elements is in progress, and a micro-LED element having a size of about 7 μm has been announced at a conference (see NPL 1).

### CITATION LIST

### Patent Literature

PTL 1: Japanese Unexamined Patent Application Publication No. 2009-272591 (published on Nov. 19, 2009)
PTL 2: Japanese Unexamined Patent Application Publication (Translation of PCT Application) No. 2016-503958 (published on Feb. 8, 2016)

### Non Patent Literature

NPL 1: Francois Olivier, Anis Daami, Ludovic Dupre, Franck Henry, Bernard Aventurier, Francois Templier, “Investigation and Improvement of 10 μm Pixel-pitch GaN-based Micro-LED Arrays with Very High Brightness”, SID 2017 DIGEST, P 353, 2017

### SUMMARY OF INVENTION

### Technical Problem

However, the micro-LED elements disclosed in PTLs 1 and 2 and NPL 1 described above have problems as follows.

Firstly, the micro-LED element has a problem in that external quantum efficiency (ratio of emission power to input power) becomes very small in a case where miniaturization of micro-LED elements is in progress as disclosed in NPL 1. Specifically, in a micro-LED element having a size smaller than 10 μm, the external quantum efficiency of the micro-LED element is smaller than 11%. On the other hand, the external quantum efficiency of an LED element having a normal size (for example, 100 μm to 1000 μm or less) is about 30% to 60%. As described above, the micro-LED element having a size smaller than 10 μm has external quantum efficiency which is significantly lower than that of the LED element having a normal size. Micro-LED displays are expected to have high light emission efficiency. Therefore, low external quantum efficiency is a very serious problem for the micro-LED displays.

Further, there is a problem that the light emission efficiency in the entire micro-LED element is decreased more as the miniaturization of the micro-LED element is advanced more. This is because, as the miniaturization of the micro-LED element is advanced more, that is, as the area of the micro-LED element is reduced more, the ratio of the area of the outer peripheral portion to the area of the micro-LED element increases more. As described in NPL 1, in the micro-LED element, the light emission efficiency at the outer peripheral portion is lower than the light emission efficiency at portions other than the outer peripheral portion. Thus, as the miniaturization of the micro-LED element is advanced more, the ratio of the portion having lower light emission efficiency in the micro-LED element increases. As a result, the light emission efficiency in the entire micro-LED element is decreased. This is a major obstacle to advancement of high definition or cost reduction of the micro-LED display, which is obtained by miniaturization of the micro-LED element.

The present invention has been made in view of the above problems, and the object thereof is to provide a micro-LED element and a production method of the micro-LED element, in which it is possible to suppress a decrease in light emission efficiency in comparison to a micro-LED element in the related art even in a case where the size of the micro-LED element is reduced. Another object of the present invention is to provide an image display element including a plurality of such micro-LED elements.

### Solution to Problem

To solve the above problems, according to an aspect of the present invention, a micro-LED element includes a nitride semiconductor layer in which an N-type layer, a light-emitting layer, and a P-type layer are stacked in this order when viewed from a light emission surface side, and a P-side electrode layer formed on the P-type layer side. The N-type layer includes a first region in contact with the light-emitting layer and a second region including the light emission surface.

In the micro-LED element, an angle between a first interface surrounding at least a side of the first region in the nitride semiconductor layer and the light-emitting layer is a prescribed first angle at which light propagating in a direction along the light-emitting layer is reflected in a direction toward the light emission surface. An angle between a second interface surrounding a side of the second region in the nitride semiconductor layer and the light-emitting layer is a prescribed second angle larger than the first angle. The first interface is surrounded by a transparent buried layer, the second interface is not covered by the buried layer, and another side surface of the buried layer forms a flat surface continuously connected with the second interface in the entire circumference when viewed from the light emission surface side. In the micro-LED element, in a case of being viewed from the P-side electrode layer side in plan view, the P-side electrode layer is formed in a region covering an entirety of the light-emitting layer.

To solve the above problems, according to another aspect of the present invention, a production method includes a first deposition step of obtaining a nitride semiconductor layer by depositing an N-type layer, a light-emitting layer, and a P-type layer on a growth substrate in this order, a first etching step of forming a first groove portion by etching a portion of the nitride semiconductor layer, and providing a first region having an etched side and a second region being a region other than the first region in the N-type layer, a second deposition step of depositing a buried layer on the first groove portion, a polishing step of polishing a surface of the buried layer, a P-side electrode layer forming step of forming a P-side electrode layer on the surface polished in the polishing step, and a second etching step of forming a second groove portion exposing a portion of the growth substrate, by etching the buried layer and the second region.

In the production method, in the first etching step, the first groove portion is formed such that an angle between a first interface surrounding at least a side of the first region in the nitride semiconductor layer and the light-emitting layer is a prescribed first angle at which light propagating in a direction along the light-emitting layer is reflected in a direction toward a light emission surface. In the second etching step, the second groove portion is formed such that an angle between a second interface surrounding a side of the second region in the nitride semiconductor layer and the light-emitting layer is a prescribed second angle larger than the first angle. The second etching step is performed after the first etching step.

To solve the above problems, according to still another aspect of the present invention, a production method includes a first deposition step of obtaining a nitride semiconductor layer by depositing an N-type layer, a light-emitting layer, and a P-type layer on a growth substrate in this order, a first etching step of forming a first groove portion by etching a portion of the nitride semiconductor layer, and providing a first region having an etched side and a second region being a region other than the first region in the N-type layer, a second deposition step of depositing a protective layer on the nitride semiconductor layer, a contact hole forming step of forming a contact hole in the protective layer to expose a portion of the first region, a P-side electrode layer forming step of forming a P-side electrode layer to cover an entirety of the light-emitting layer and cover the contact hole in a case of being viewed from an opposite side of the growth substrate in plan view, and a second etching step of forming a second groove portion exposing a portion of the growth substrate, by etching the protective layer and the second region.

In the production method, in the first etching step, the first groove portion is formed such that an angle between a first interface surrounding at least a side of the first region in the nitride semiconductor layer and the light-emitting layer is a prescribed first angle at which light propagating in a direction along the light-emitting layer is reflected in a direction toward a light emission surface. In the second etching step, the second groove portion is formed such that an angle between a second interface surrounding a side of the second region in the nitride semiconductor layer and the light-emitting layer is a prescribed second angle larger than the first angle. The second etching step is performed after the first etching step.

### Advantageous Effects of Invention

According to an aspect of the present invention, it is possible to provide a micro-LED element in which it is possible to suppress a decrease in light emission efficiency in comparison to a micro-LED element in the related art even in a case where the size of the micro-LED element is reduced, an image display element including a plurality of such micro-LED elements, and a production method of such a micro-LED element.

### BRIEF DESCRIPTION OF DRAWINGS

FIG. 1(a) is a sectional view illustrating an image display element including a plurality of the micro-LED elements according to a first embodiment of the present invention. FIG. 1(b) is a plan view in a case where the micro-LED element illustrated in FIG. 1(a) is viewed from a P-side electrode layer side.

FIG. 2 is a flowchart illustrating a production method of the micro-LED element illustrated in FIG. 1.

FIGS. 3(a) to 3(e) are sectional views illustrating the micro-LED element in each step of the production method illustrated in FIG. 2.

FIG. 4 is a flowchart illustrating a production method of the image display element illustrated in FIG. 1.

FIGS. 5(a) to 5(c) are sectional views illustrating the image display element in each step of the production method illustrated in FIG. 4.

FIGS. 6(a) to 6(e) are sectional views illustrating a micro-LED element in each step of a production method of producing the micro-LED element according to a first modification example of the first embodiment of the present invention.

FIGS. 7(a) to 7(e) are sectional views illustrating a micro-LED element in each step of a production method of producing the micro-LED element according to a second modification example of the first embodiment of the present invention.

FIGS. 8(a) to 8(d) are sectional views illustrating a micro-LED element in each step of a production method of producing the micro-LED element according to a third modification example of the first embodiment of the present invention.

FIG. 9(a) is a sectional view illustrating an image display element including a plurality of the micro-LED elements according to a second embodiment of the present invention. FIG. 9(b) is a plan view in a case where the micro-LED element illustrated in FIG. 9(a) is viewed from a P-side electrode layer side.

FIG. 10 is a flowchart illustrating a production method of the micro-LED element illustrated in FIG. 9.

FIGS. 11(a) to 11(e) are sectional views illustrating the micro-LED element in each step of the production method illustrated in FIG. 10.

FIG. 12 is a flowchart illustrating a production method of the image display element illustrated in FIG. 9.

FIGS. 13(a) to 13(c) are sectional views illustrating the image display element in each step of the production method illustrated in FIG. 12.

FIG. 14 is a flowchart illustrating a production method of a micro-LED element according to a third embodiment of the present invention.

FIGS. 15(a) to 15(f) are sectional views illustrating the micro-LED element in each step of the production method illustrated in FIG. 14.

### DESCRIPTION OF EMBODIMENTS

### First Embodiment

(Configuration of Micro-LED Element 100_{i,j})

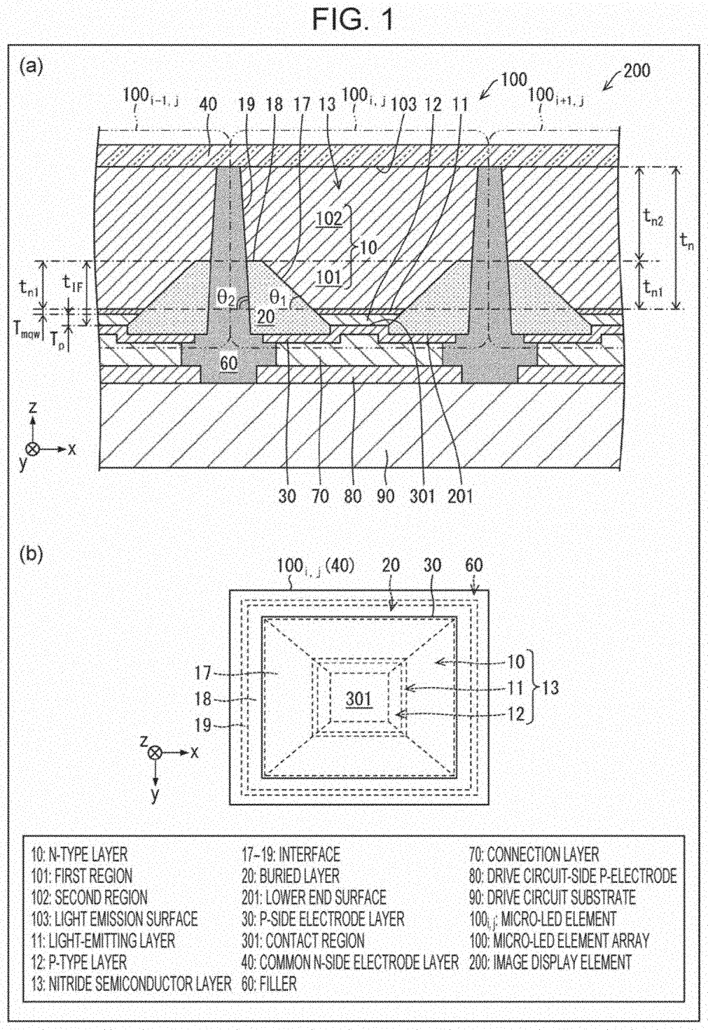

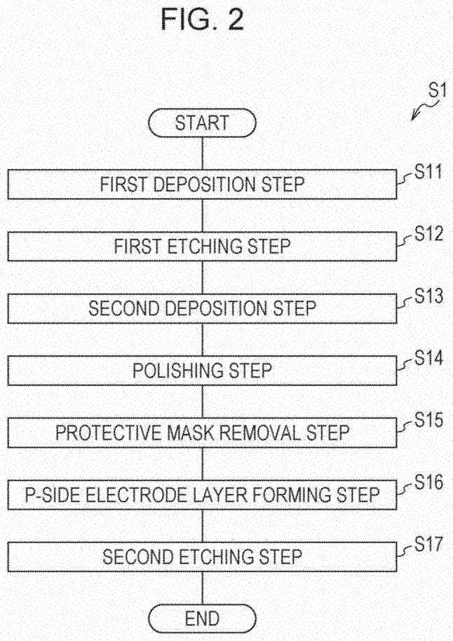

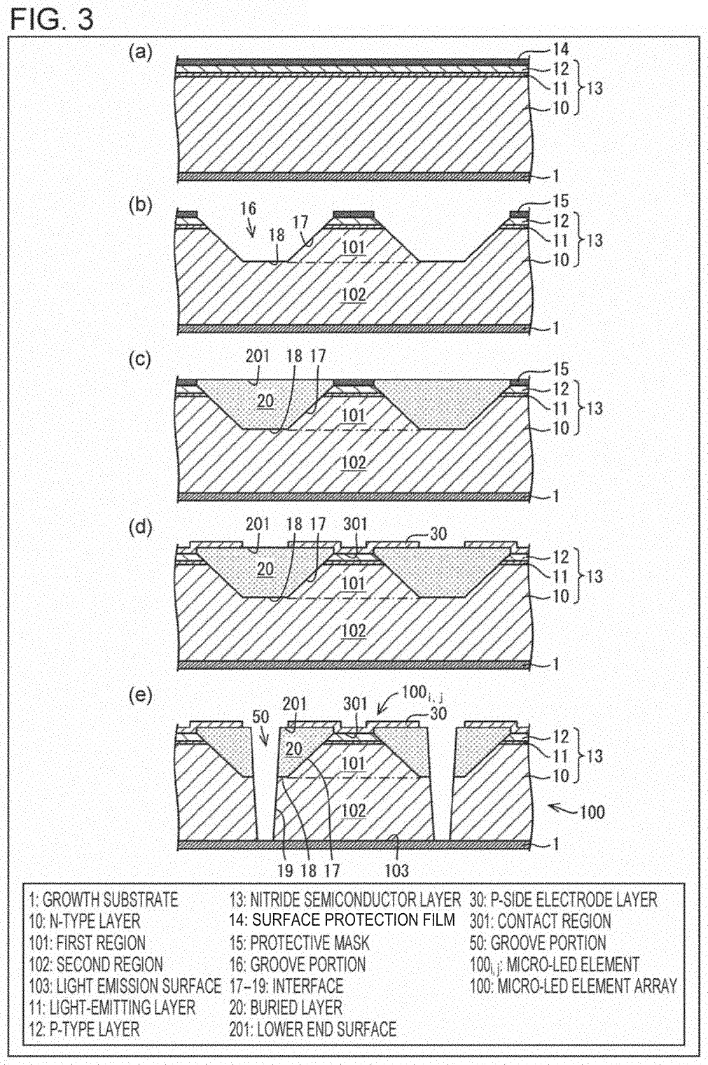

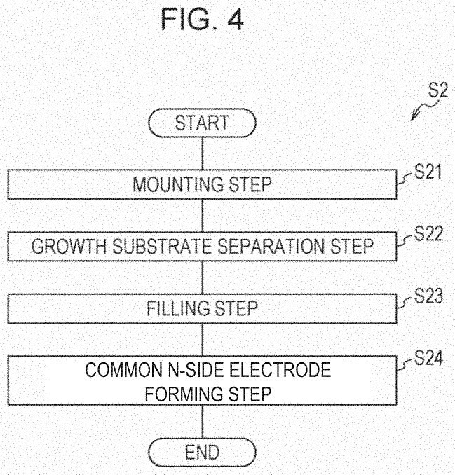

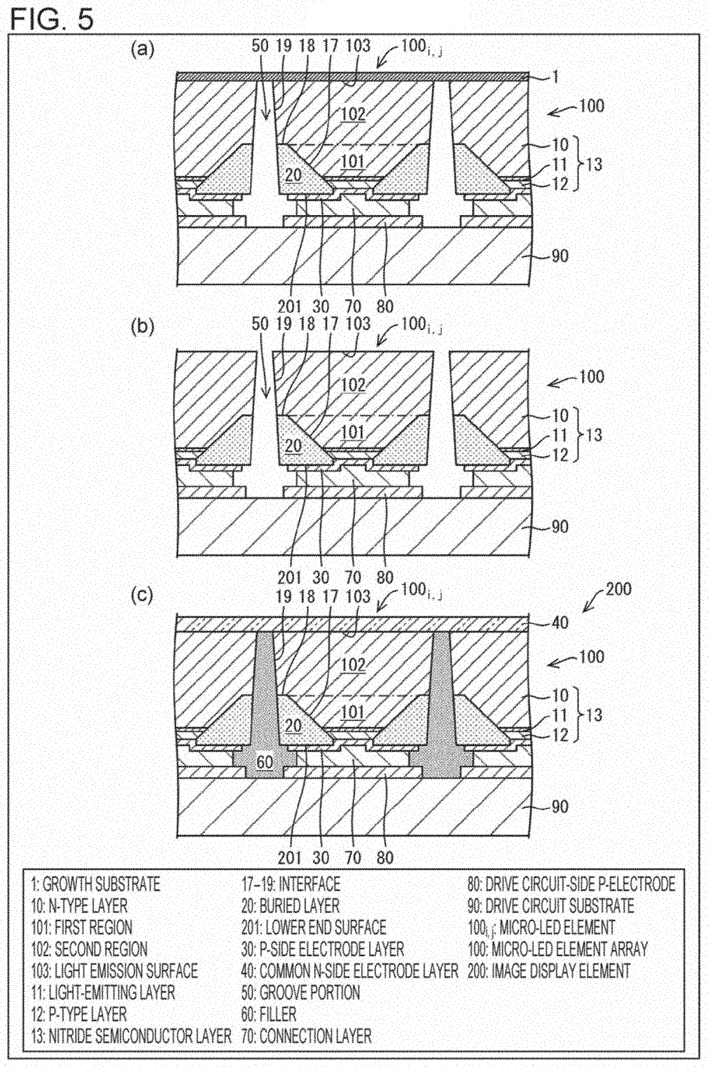

Hereinafter, an image display element 200 in which a micro-LED element 100_{i,j} according to a first embodiment of the present invention is mounted as a light source will be described with reference to FIGS. 1 to 5. FIG. 1(a) is a sectional view illustrating the image display element 200 including a plurality of the micro-LED elements 100_{i,j}. FIG. 1(b) is a plan view in a case where the micro-LED element 100_{i,j} is viewed from a P-side electrode layer 30 side. FIG. 2 is a flowchart illustrating a production method S1 of the micro-LED element 100_{i,j}. FIGS. 3(a) to 3(e) are sectional views illustrating the micro-LED element 100_{i,j} in each step of the production method S1. FIG. 4 is a flowchart illustrating a production method S2 of the image display element 200. FIGS. 5(a) to 5(c) are sectional views illustrating the image display element 200 in each step of the production method S2.

In FIG. 1, a normal direction to the surface of a drive circuit substrate 90 is defined as a z-axis direction. In a plane parallel to the surface of the drive circuit substrate 90, a direction along a long side of the micro-LED element 100_{i,j} is defined as an x-axis direction, and a direction along a short side of the micro-LED element 100_{i,j} is defined as a y-axis direction. Further, a direction toward a common N-side electrode layer 40 from the drive circuit substrate 90 in the z-axis direction is defined as a z-axis positive direction, and an x-axis positive direction and a y-axis positive direction are defined to form a right-handed orthogonal coordinate system along with the z-axis positive direction. The z-axis positive direction is referred to as an upward direction below, and a z-axis negative direction is referred to as a downward direction below.

As illustrated in FIG. 1, the micro-LED element 100_{i,j} includes a nitride semiconductor layer 13, a buried layer 20, a P-side electrode layer 30, and a common N-side electrode layer 40. The nitride semiconductor layer 13 includes an N-type layer 10, a light-emitting layer 11, and a P-type layer 12. In a case where the nitride semiconductor layer 13 is viewed from a light emission surface side, the N-type layer 10, the light-emitting layer 11, and the P-type layer 12 are stacked in this order. The P-side electrode layer 30 is formed on a P-type layer 12 side (lower side) of the nitride semiconductor layer 13 and is in contact with the P-type layer 12. The common N-side electrode layer 40 is formed on the N-type layer 10 side of the nitride semiconductor layer 13 and is in contact with the N-type layer 10. As described above, the micro-LED element 100_{i,j} is a so-called micro-LED element of an upper and lower electrode type.

In the micro-LED element 100_{i,j} configured as described above, light generated in the light-emitting layer 11 is emitted from a side (z-axis positive direction side) on which the common N-side electrode layer 40 is formed. Thus, in the micro-LED element 100_{i,j} a surface of the common N-side electrode layer 40 on an opposite side of the N-type layer 10 serves as a light emission surface. In the nitride semiconductor layer 13, an interface between the N-type layer 10 and the common N-side electrode layer 40 functions as the light emission surface.

In the micro-LED element 100_{i,j}, the N-type layer 10 includes a first region 101 being a region on the z-axis negative direction side and a second region 102 being a region on the z-axis positive direction side. The first region 101 is in contact with the light-emitting layer 11. The second region is spaced from the light-emitting layer 11 and includes the light emission surface on the N-type layer 10.

An angle 68 between an interface 17 and the surface of the light-emitting layer 11 is set to an angle at which light propagating in a direction (for example, x-axis direction or y-axis direction) along the surface of the light-emitting layer 11 is reflected in a direction (z-axis positive direction) toward the light emission surface. The interface 17 surrounds sides of the first region 101, the light-emitting layer 11, and the P-type layer 12 in the nitride semiconductor layer 13. The interface 17 and the angle θ₁ correspond to a first interface and a prescribed first angle described in claims, respectively. In the first embodiment, the angle θ₁ is 45 degrees.

An angle θ₂ between an interface 19 surrounding a side of the second region 102 in the nitride semiconductor layer 13 and the surface of the light-emitting layer 11 is set to be larger than the first angle (θ₁=45 degrees). The interface 19 and the angle θ₂ correspond to a second interface and a prescribed second angle described in claims, respectively. In the first embodiment, the angle θ₂ is 80 degrees.

In the micro-LED element 100_{i,j}, an interface 18 forming an angle of 0 degrees with the surface of the light-emitting layer 11 is further provided between the interface 17 and the interface 19. The interface 18 may be omitted in accordance with the angle θ₁ and the size of the micro-LED element 100_{i,j}.

The image display element 200 includes a drive circuit substrate 90 and a plurality of the micro-LED elements 100_{i,j} which are stacked on the surface of the drive circuit substrate 90 in a two-dimensional array. In the first embodiment, the plurality of the micro-LED elements 100_{i,j} means a micro-LED element disposed in an i-th row and a j-th column (indicating a certain position) among micro-LED elements arranged in a two-dimensional array of n rows and m columns (n and m are any positive integers). That is, i is any integer in a range of 1≤i≤n, and j is any integer in a range of 1≤j≤m. The plurality of the micro-LED elements 100_{i,j} arranged in a two-dimensional array is referred to as a micro-LED element array 100.

A drive circuit configured to supply a drive current to each of the plurality of the micro-LED elements 100_{i,j} is formed in the drive circuit substrate 90. In FIG. 1, only a drive circuit-side P-electrode 80 being one electrode connected to the drive circuit is illustrated, and a drive circuit-side N-electrode is not illustrated.

In each of the plurality of the micro-LED elements 100_{i,j}, the P-side electrode layer 30 is connected to the drive circuit-side P-electrode 80 with a connection layer 70, and the common N-side electrode layer 40 is connected to the drive circuit-side N-electrode (not illustrated). When the drive current is supplied from the drive circuit of the drive circuit substrate 90 to the plurality of the micro-LED elements 100_{i,j}, each of the plurality of the micro-LED elements 100_{i,j} emits light. Intensity of the light emitted by the micro-LED element 100_{i,j} is determined in accordance with the magnitude of the drive current. The micro-LED element 100_{i,j} may further include a wavelength conversion layer, a light diffusing layer, a color filter, or the like disposed on a light emission side (side from the common N-side electrode layer 40 in the z-axis positive direction). However, since the wavelength conversion layer, the light diffusing layer, the color filter, and the like have no direct relation with the micro-LED element 100_{i,j}, the wavelength conversion layer, the light diffusing layer, the color filter, and the like are not illustrated.

As described above, the entire circumference of the sides of the first region 101, the light-emitting layer 11, and the P-type layer 12 in the nitride semiconductor layer 13 is covered by the interface 17. In the first embodiment, in plan view, the micro-LED element 100_{i,j} is formed to have a rectangular outline. In this case, the interface 17 is configured by four planes. The four planes are arranged to form side surfaces of a truncated quadrangular pyramid having a rectangular bottom surface.

In plan view, the outline of the micro-LED element 100_{i,j} may be another polygon (for example, regular hexagon), a circle, or an ellipse instead of a rectangle (including a square). For example, in a case where the outline in plan view is an N-sided polygon (N is an integer of 3 or more), the interface 17 is configured by N planes. The N planes are arranged to form side surfaces of a truncated N-sided pyramid having a bottom surface of an N polygon. For example, in a case where the outline in plan view is a circle, the interface 17 is configured by one curved plane. The one curved plane is disposed to form a side surface of a truncated cone.

As described above, the angle θ₁ is set to 45 degrees. As will be described later, the interface 17 is formed by etching (see a first etching step S12 illustrated in FIG. 2) a portion of the nitride semiconductor layer 13. The angle θ₁ in a produced micro-LED element 100_{i,j} in practice depends on precision of the etching and fluctuates in a substantially certain range. In a case where dry etching is employed as an etching method in the first etching step S12, fluctuation of the angle θ₁ due to the precision of etching is estimated to be about ±10 degrees. Thus, the angle θ₁ in a produced micro-LED element 100_{i,j} in practice is not limited to the angle θ₁ being the prescribed angle and may be in a prescribed angle range centering on the angle θ₁, that is, in a range of the angle θ₁±10 degrees. The above-described fluctuation of the angle θ₁ may change depending on the etching method employed in the first etching step S12 described later.

The angle θ₁ is preferably 45 degrees in order to cause light propagating in a direction along the surface of the light-emitting layer 11 to be reflected in a direction along the normal direction of the light-emitting layer 11. However, the angle θ₁ may be defined to be angle within a range of 35 degrees to 55 degrees.

In the first embodiment, the interface 17 is formed to surround the side of the first region 101 of the N-type layer 10, the side of the light-emitting layer 11, and the side of the P-type layer 12. Thus, a thickness t_{IF} (length in the z-axis direction) of a region in which the interface 17 is formed is given as the sum of the thickness tₙ₁ of the first region 101, the thickness t_{mqw} of the light-emitting layer 11, and the thickness tₚ of the P-type layer 12 (t_{IF}=tₙ₁+t_{mqw}+tₚ).

As described above, the angle θ₂ is set to 80 degrees. The angle θ₂ may be set to any value in a range exceeding the angle θ₁, and the angle θ₂ is preferably close to 90 degrees. Similar to a case of the angle θ₁ in the micro-LED element 100_{i,j} produced in practice, the angle θ8 in the micro-LED element 100_{i,j} produced in practice is not limited to the angle θ₂ being the prescribed angle, and may be within a range of the angle θ2±10 degrees.

As illustrated in FIG. 1(a), the outer side of the interface 17 is covered by the buried layer 20. A lower end surface 201 of the buried layer 20 is polished to be flat along an xy plane (see a polishing step S14 illustrated in FIG. 2). That is, the lower end surface 201 has high surface flatness.

A region (region in contact with the contact region 301 of the P-side electrode layer 30) exposed from the buried layer 20 in the P-type layer 12 is located slightly on the z-axis positive direction side from the lower end surface 201. A step between the exposed region and the lower end surface 201 is equal to or smaller than 100 nm, and this is much smaller than the thickness t_{IF}.

The buried layer 20 is preferably formed of a material which is transparent to visible light and has a refractive index smaller than a refractive index of a material forming the nitride semiconductor layer 13. Examples of the preferable material forming the buried layer 20 include SiO₂.

The P-side electrode layer 30 covers substantially the entirety of the lower end surface 201 and has high surface flatness continuing from the lower end surface 201 of the buried layer 20. Thus, the lower end surface of the P-side electrode layer 30 has high surface flatness, similar to the lower end surface 201.

The interface 17 is capable of reflecting light emitted from the light-emitting layer 11 in the direction along the surface of the light-emitting layer 11, in the direction (that is, upward direction) toward the light emission surface. Therefore, the micro-LED element 100_{i,j} can emit light emitted from the light-emitting layer 11 in the direction along the surface of the light-emitting layer 11, from the light emission surface with high efficiency, in addition to light emitted from the light-emitting layer 11 in the upward direction (z-axis positive direction). Thus, in the micro-LED element 100_{i,j} it is possible to largely improve light emission efficiency in comparison to a micro-LED element in the related art, in which the interface 17 is not provided. In other words, in the micro-LED element 100_{i,j}, it is possible to suppress decrease of light emission efficiency in comparison to the micro-LED element in the related art, even if the size of the micro-LED element is reduced.

### First Example

A micro-LED element 100_{i,j} as a first example of the present invention will be described below. The micro-LED element 100_{i,j} in the first example is obtained by employing a configuration as follows in the micro-LED element 100_{i,j} illustrated in FIG. 1.
Outline in plan view: square in which the length of one side is about 7 μm
tₚ=100 nm
t_{mqw}=70 nm
tₙ₁=1500 nm
θ₁=45 degrees

A micro-LED element in which the interface 17 and the buried layer 20 are removed from the configuration of the micro-LED element 100_{i,j} in the first example is used as a first comparative example.

In a state where the same drive current is supplied to the micro-LED elements, light outputs of the micro-LED element 100_{i,j} in the first example and the micro-LED element in the first comparative example are measured. As a result, the light output of the micro-LED element 100_{i,j} in the first example is 210% of the light output of the micro-LED element in the first comparative example.

The inventor of the present application has estimated that the following points contribute to the factor of the significant increase in the light output. Firstly, the large interface 17 (interface 17 having a thickness t_{IF} thicker than the thickness tₚ) is provided, and the outer side of the interface 17 is surrounded by the thick transparent buried layer 20 made of a low-refractive-index material. Thus, light emitted from the light-emitting layer 11 in a horizontal direction (direction along the surface of the light-emitting layer 11) and to the periphery of the light-emitting layer 11 is totally reflected upward (in the z-axis positive direction). Secondly, the reflected light is substantially vertically incident to the light emission surface of the N-type layer 10 and then is emitted to the outside thereof.

If the interface 17 is not provided, such light is emitted from the light-emitting layer 11 in the horizontal direction and then absorbed by the surrounding metal layer and the like, or is attenuated in the process of repeating reflection in the nitride semiconductor layer 13. That is, such light is not emitted to the outside.

On the contrary, in the micro-LED element 100_{i,j} in the first example, total reflection occurs at the interface 17, and thus the light emitted from the light-emitting layer 11 in the horizontal direction is reflected upward.

Accordingly, there is almost no light loss. Since the reflected light by reflection at the interface 17 is substantially vertically incident to the light emission surface of the N-type layer 10, it is possible to shorten the length of a light path in a case where the light is transmitted through the N-type layer 10. Thus, absorption of the reflected light in the N-type layer 10 is hard to occur. As results, the micro-LED element 100_{i,j} in the first example has very high light extraction efficiency.

In the micro-LED element 100_{i,j}, the interface 17 is inclined from the surface of the light-emitting layer 11.

Therefore, the area of the light-emitting layer 11 is much smaller than the area of the micro-LED element 100_{i,j}. In the first example, a ratio of the area of the light-emitting layer 11 to the area of the micro-LED element 100_{i,j} is (7000−(70+1500)*2)\hat{ }2/7000\hat{ }2=0.304, and this is about 30%.

Further, since the peripheral portion of the light-emitting layer 11 is damaged by dry etching of the nitride semiconductor layer 13, it is considered that the area of the light-emitting layer 11, which effectively contributes to light emission is much smaller. Since the damaged portion consumes a current without emitting light, it is estimated that the light emission efficiency is decreased.

Such an effect appears as a decrease in internal quantum efficiency of the micro-LED element 100_{i,j}.

The internal quantum efficiency and the light extraction efficiency are separated from each other using data of current dependency of the external quantum efficiency, and the internal quantum efficiency is evaluated. As a result, the internal quantum efficiency of the micro-LED element 100_{i,j} in the first example is 69%, and the internal quantum efficiency of the micro-LED element in the first comparative example is 70%, and there is no large difference in internal quantum efficiency between the first example and the first comparative example. Thus, it is understood that improvement more than twice in light emission efficiency of the micro-LED element 100_{i,j} in the first example is mainly caused by improvement of the light extraction efficiency.

The area of the light-emitting layer 11 is about ⅓ of the area of the light-emitting layer in the micro-LED element in the first comparative example. Normally, in a case where the area of the light-emitting layer 11 is reduced, the internal quantum efficiency is to be largely decreased. However, it is estimated that the reason that the internal quantum efficiency of the micro-LED element 100_{i,j} in the first example is not largely deteriorated in comparison to the internal quantum efficiency of the micro-LED element in the first comparative example is that damages on the light-emitting layer 11 is significantly reduced.

In this structure, the area of the P-type layer 12 is much smaller than the area of the micro-LED element 100_{i,j}. Regardless of this, the area of the P-side electrode layer 30 is substantially equal to the area of the micro-LED element 100_{i,j}, and the surface of the P-side electrode layer 30 is flat. Since it is possible to form the P-side electrode layer 30 having a wide area and a flat surface regardless of the small area of the P-type layer 12, the micro-LED element 100_{i,j} is stably and firmly connected to the drive circuit-side P-electrode 80 with the connection layer 70. Thus, it is possible to reduce defects occurring, for example, in a manner that the micro-LED element 100_{i,j} is pulled by the growth substrate 1 and thus is chipped off or that the micro-LED element 100_{i,j} is inclined by a mechanical impact, when the growth substrate 1 is separated from the N-type layer 10 in a growth substrate separation step S22 (see FIG. 4) described later.

(Production Method S1 of Micro-LED Element 100_{i,j})

Next, a production method S1 as an example of a production method of the micro-LED element 100_{i,j} will be described with reference to FIGS. 2 and 3.

As illustrated in FIG. 2, the production method S1 includes a first deposition step S1, a first etching step S12, a second deposition step S13, a polishing step S14, a protective mask removal step S15, a P-side electrode layer forming step S16, and a second etching step S17.

As illustrated in FIG. 3(a), the first deposition step S11 is a step of obtaining the nitride semiconductor layer 13 by depositing the N-type layer 10, the light-emitting layer 11, and the P-type layer 12 on the growth substrate 1 in this order. As a material forming the growth substrate 1, for example, sapphire (Al₂O₃) or SiC may be used. As the material forming the nitride semiconductor layer 13, for example, a GaN-based semiconductor may be used. As an apparatus of growing the nitride semiconductor layer 13 on the growth substrate 1, for example, a MOCVD apparatus may be used. The growth substrate 1 may have a textured structure on the surface.

The light-emitting layer 11 includes a multiple-quantum well layer formed with an InGaN layer and a GaN layer. Each of the N-type layer 10 and the P-type layer 12 is configured with a complicated multi-layer structure. In the first embodiment, specific configurations of the N-type layer 10, the light-emitting layer 11, and the P-type layer 12 are not particularly limited. For example, the configurations of the N-type layer, the light-emitting layer, and the P-type layer, which are employed in the micro-LED element in the related art may be appropriately employed. Thus, in the first embodiment, descriptions for the specific configurations of the N-type layer 10, the light-emitting layer 11, and the P-type layer 12 will be omitted.

The thickness tₙ of the N-type layer 10 (sum of the thickness tₙ₁ of the first region 101 and the thickness tₙ₂ of the second region 102) is generally equal to or smaller than 10 μm and is about 5 μm±2 μm in many cases. The thickness t_{mqw} of the light-emitting layer 11 is generally 10 nm to 200 nm and is about 50 nm to 100 nm in many cases. The thickness tₚ of the P-type layer 12 is generally 50 nm to 1000 nm and is about 100 nm to 300 nm in many cases.

In the production method S1, the growth of the nitride semiconductor layer 13 is finished, and then a surface protection film 14 is formed. As described above, the first deposition step S11 may include formation of the surface protection film 14.

As illustrated in FIG. 3(b), the first etching step S12 is a step of forming a groove portion 16 by etching a portion of the nitride semiconductor layer 13 and providing the first region 101 having an etched side and the second region 102 being a region other than the first region 101, in the N-type layer 10. In the first etching step S12, the groove portion 16 is formed such that the angle θ₁ between at least the surface of the interface 17 and the light-emitting layer 11 in the nitride semiconductor layer 13 is set to 45 degrees being the prescribed first angle, that is, the angle θ₁ between the surface of a side wall of the groove portion 16 and the surface of the light-emitting layer 11 is set to 45 degrees. The groove portion 16 is a first groove portion described in claims.

In the first embodiment, the groove portion 16 is formed such that the bottom surface of the groove portion 16 is parallel to the surface of the light-emitting layer 11. The bottom surface forms an interface 18.

In order to form the groove portion 16, firstly, a resist pattern having an opening portion on the groove portion 16 is formed using a general photolithography step.

Then, the surface protection film 14, the P-type layer 12, the light-emitting layer 11, and a portion of the N-type layer 10 are etched by a dry etching apparatus. With the above step, the groove portion 16 is formed. The first etching step S12 is performed, and thereby a protective mask 15 being the remaining portion of the surface protection film 14 remains on the surface of the P-type layer 12, and the surrounding of the protective mask 15 is surrounded by the interface 17. In this manner, the interface 17 surrounding the side of the first region 101 is formed. The depth of the groove portion 16 is equal to the thickness t_{IF} of the above-described interface 17.

The second deposition step S13 is a step of depositing the buried layer 20 on the groove portion 16. The buried layer 20 is formed, for example, by a CVD method with SiO₂ (silicon dioxide).

The polishing step S14 is a step of removing SiO₂ deposited on the surface of the protective mask 15 by polishing the surface of the protective mask 15 and the buried layer 20. As a method of polishing the surface of the protective mask 15 and the buried layer 20, for example, a CMP (chemical mechanical polishing) method may be employed.

The second deposition step S13 and the polishing step S14 are performed, and thereby, as illustrated in FIG. 3(c), a structure in which the protective mask 15 and the surface of the buried layer 20 are polished to be flat is obtained. The protective mask 15, that is, the surface protection film 14 is preferably formed of a material functioning as a stopper in the polishing step S14. As the material functioning as a stopper, in other words, the material having difficulty in being etched, for example, SiN (silicon nitride) is exemplified. The protective mask 15 may slightly remain after the polishing step S14 is performed. The thickness of the surface protection film 14 before the polishing step S14 is performed is about 30 nm to 100 nm.

The protective mask 15 is capable of preventing exposure of the surface of the P-type layer 12 to a polishing liquid or a polishing pad during the polishing step S14, in addition to the function as the stopper of the CMP. The protective mask 15 is formed, and thereby effects as follows are obtained: an occurrence of contact failure by thinning the film of the P-type layer 12 is suppressed, and the decrease in light emission efficiency by metal contamination of the nitride semiconductor layer 13 is prevented.

The protective mask removal step S15 is a step of removing the protective mask 15.

As illustrated in FIG. 3(d), the P-side electrode layer forming step S16 is a step of forming the P-side electrode layer 30 on the surface of the buried layer 20, which has been polished in the polishing step S14. Since the protective mask 15 is removed in the protective mask removal step S15, the P-side electrode layer 30 formed on the surface of the buried layer 20 is in contact with the P-type layer 12. The P-side electrode layer forming step S16 may include an activation annealing step performed before the P-side electrode layer 30 is formed. The P-type layer 12 is activated by performing the activation annealing step.

As illustrated in FIG. 1(b), when the micro-LED element 100_{i,j} is viewed from the z-axis negative direction side in plan view, it is preferable that the P-side electrode layer 30 is formed in the region that completely covers the light-emitting layer 11, and it is more preferable that the P-side electrode layer 30 covers an area as wide as possible, on the surface of the micro-LED element 100_{i,j} on the z-axis negative direction side. The surface of the P-side electrode layer 30 is flat except for a small step of about several tens of nm caused by removing the protective mask 15.

As the P-side electrode layer 30, for example, a multilayer film made of palladium, aluminum, nickel, platinum, and gold may be employed. Such a multilayer film may be formed, for example, using an electron beam evaporation method. In a case where the P-side electrode layer 30 is formed using the electron beam evaporation method, a resist pattern having an opening portion in the region for forming the P-side electrode layer 30 is formed, and evaporation for the multilayer film is performed. Then, the P-side electrode layer 30 is obtained using a lift-off method of removing the resist pattern with ultrasonic vibration or a chemical solution. The P-side electrode layer 30 may be obtained even in a manner that deposition is performed for the multilayer film made of palladium, aluminum, nickel, titanium, titanium nitride, aluminum copper alloys, and the like, the resist pattern that covers the region for forming the P-side electrode layer 30 is provided, and the multilayer film formed in an unnecessary region is removed by dry etching.

As illustrated in FIG. 3(e), the second etching step S17 is a step of exposing a portion of the growth substrate 1 by performing dry etching on portions of the buried layer 20 and the second region 102. A groove portion 50 is formed by performing the second etching step S17.

Here, in the second etching step S17, the groove portion 50 is formed such that the angle θ₂ being the prescribed second angle is greater than the angle θ₁ being the prescribed first angle. The groove portion 50 is a second groove portion described in claims. The nitride semiconductor layer 13 and the buried layer 20 formed on one growth substrate 1 are divided into a plurality of the micro-LED elements 100_{i,j} arranged in a two-dimensional array, by performing the second etching step S17. That is, a micro-LED element array 100 is obtained.

The groove portion 50 is formed in a manner that the resist pattern having an opening portion at the outer peripheral portion of the micro-LED element 100_{i,j} is provided, the buried layer 20 is subjected to dry etching, and then the second region 102 of the nitride semiconductor layer 13 is etched.

It is possible to increase the area of the emission surface of the micro-LED element 100_{i,j} as large as possible, by setting the angle θ₂ to be larger than the angle θ₁.

The dry etching used in the second etching step S17 is required for forming the groove portion 50 in which the angle θ₂ is substantially perpendicular to the thick nitride semiconductor layer 13. Therefore, energy of ions in plasma used in dry etching tends to be high, and ions having high energy are also incident to the side wall of the groove portion 50, which has been etched already, during etching. If the ions hit on the light-emitting layer 11, crystal defects are generated, and this causes a decrease in light emission efficiency. However, in the micro-LED element 100_{i,j}, the light-emitting layer 11 is spaced from the groove portion 50, and the side of the light-emitting layer 11 is covered by the buried layer 20. Thus, it is possible to significantly reduce a possibility that the ions having high energy hit on the light-emitting layer 11. Thus, in the production method S1, it is possible to significantly reduce the damage on the light-emitting layer 11 which may occur in the second etching step S17. That is, even in a case where the micro-LED element 100_{i,j} is miniaturized, it is possible to suppress the decrease in internal quantum efficiency.

The second etching step S17 is a step using plasma having largest energy of ions in the production method S1 and is a step in which the light-emitting layer 11 may be largely damaged. However, as described above, in the production method S1, it is possible to significantly reduce the damage on the light-emitting layer 11.

In the dry etching used in the first etching step S12, a period in which the light-emitting layer 11 is exposed is mainly a period in which the P-type layer 12 is etched. A period in which the end portion of the light-emitting layer 11 is exposed to plasma is short. Since the angle θ₁ at the groove portion 16 is smaller than the angle θ₂ at the groove portion 50, it is not necessary to increase the energy of ions to be incident as in the dry etching used in the second etching step S17. For the above reasons, damage on the light-emitting layer 11, which may occur in the first etching step S12 is smaller than damage on the light-emitting layer 11, which may occur in the second etching step S17.

The production method S1 may additionally include a step of annealing the nitride semiconductor layer 13 (for example, annealing the nitride semiconductor layer 13 in a hydrogen atmosphere), a step of forming a very thin GaN layer having high resistance, on the surface (that is, interface 17 and interface 18) of the groove portion 16, after the first etching step S12.

In the production method S1, etching of the groove portion 16 is separated from etching of the groove portion 50. Thus, it is possible to expect effects of reducing damage which may occur in the light-emitting layer 11 by etching and improving the internal quantum efficiency by recovering minor defects. In addition, it is possible to evaporate In from the end portion of the multiple-quantum well layer (InGaN layer) of the light-emitting layer 11 by annealing in the hydrogen atmosphere. Thus, a low-indium region is formed at the end portion of the multiple-quantum well layer by annealing in the hydrogen atmosphere, and thus it is possible to also expect an effect of preventing an occurrence of a situation in which electrons or holes injected into the multiple-quantum well layer approach the interface at the end portion, and reducing non-emissive recombination.

As in the micro-LED element in the first comparative example described above, in a case where the interface 17 is not formed, the light-emitting layer 11 is simultaneously processed by dry etching for forming the groove portion 50.

In this case, the P-side electrode layer 30 is formed at a step at which the light-emitting layer 11 is etched. Thus, it is difficult to sufficiently increase an annealing temperature, and it is not possible to expect an effect obtained by sufficient annealing.

In FIG. 3(e), the groove portion 50 reaches the surface of the growth substrate 1. However, it is not necessary that all groove portions 50 reach the surface of the growth substrate 1. For example, among a plurality of the micro-LED elements 100_{i,j} constituting the micro-LED element array 100, some adjacent micro-LED elements 100_{i,j} may be partially joined to each other by the second region 102 of the N-type layer 10.

(Production Method S2 of Image Display Element 200)

Next, a production method S2 being an example of a production method of an image display element 200 using the micro-LED element array 100 including a plurality of the micro-LED elements 100_{i,j} will be described with reference to FIGS. 4 and 5.

Before the production method S2, the drive circuit substrate 90 on which the drive circuit configured to drive each micro-LED element 100_{i,j} is mounted is prepared. The drive circuit-side P-electrode 80 and the drive circuit-side N-electrode 81 (not illustrated) for causing a current to flow in the micro-LED element 100_{i,j} are provided on the surface of the drive circuit substrate 90. Various circuits for selecting each micro-LED element 100_{i,j} and causing a prescribed current to flow are provided in the drive circuit substrate 90, but are not directly related to the present invention. Thus, here, descriptions thereof will be omitted. Descriptions of a drive circuit-side electrode connected to the N-side electrode layer of the micro-LED element 100_{i,j} will also be omitted. The drive circuit substrate 90 may be silicon LSI itself or may include a TFT formed on glass or a film.

As illustrated in FIG. 4, the production method S2 includes a mounting step S21, a growth substrate separation step S22, a filling step S23, and a common N-side electrode forming step S24.

As illustrated in FIG. 5(a), the mounting step S21 is a step of mounting the micro-LED element array 100 on the drive circuit substrate 90. In the mounting step S21, the connection layer 70 is formed on the drive circuit-side P-electrode 80. The micro-LED element array 100 is bonded thereon, and thus the P-side electrode layer 30 is electrically connected to the drive circuit-side P-electrode 80 through the connection layer 70. At this time, a chip bonder having sufficient alignment precision is preferably used such that the corresponding P-side electrode layer 30 overlaps the drive circuit-side P-electrode 80.

The connection layer 70 may be a conductive paste printed on the drive circuit-side P-electrode 80, and a material for directly forming an alloy such as a gold bump may be used. In FIG. 5(a), the corresponding connection layer 70 is individually disposed on each drive circuit-side P-electrode 80. However, an anisotropic conductive film may be disposed on the entire surface of the drive circuit substrate 90. Alternatively, spin coating with a block copolymer (polystyrene-block-poly(2-vinylpyridine)) is performed on the drive circuit substrate 90, and the drive circuit substrate 90 is immersed in a Na₂PdCl₄ aqueous solution. Then, Pd ions are selectively precipitated on a 2-vinylpyridine core in the block copolymer, and the polymer is removed by plasma treatment. Thus, the connection layer 70 may be obtained by precipitating Pd nanoparticles having a size of several tens of nm at intervals of about 100 nm to 300 nm. This method has an advantage in that an expensive device is not required and that a connection between the P-side electrode layer 30 and the drive circuit-side P electrode 80 at room temperature is possible. Thus, this method is very preferable.

The growth substrate separation step S22 is a step of separating the growth substrate 1 from the micro-LED element array 100 by a laser separation method. As illustrated in FIG. 5(b), the light emission surface of the N-type layer 10 is exposed by separating the growth substrate 1.

The filling step S23 is a step of filling the groove portion 50 with a filler 60. Examples of a material forming the filler 60 include a high reflective material obtained by mixing a white pigment with resin and a high light-absorbing material obtained by mixing a black pigment or carbon black with resin. Any of the high reflective material and high light-absorbing material may be appropriately used in accordance with the use purpose of the image display element 200.

As illustrated in FIG. 5(c), the common N-side electrode forming step S24 is a step of forming the common N-side electrode layer 40 on the exposed light emission surface of the N-type layer 10. The common N-side electrode layer 40 forms a short circuit with the light emission surfaces of the plurality of the micro-LED elements 100_{i,j}, and thus sets the light emission surfaces of the plurality of the micro-LED elements 100_{i,j} to have potentials equal to each other. Then, the common N-side electrode layer 40 is connected to the drive circuit-side N-electrode (not illustrated in FIG. 5). Thus, the N-type layers 10 in the plurality of the micro-LED elements 100_{i,j} are connected to the drive circuit through the common N-side electrode layer 40 and the drive circuit-side N-electrode.

As the common N-side electrode layer 40, a transparent conductive film of ITO or the like may be employed. In addition, a metal mesh-like electrode in which an opening portion is provided in most of the light emission surface 103, and a metal thin film pattern is disposed on the groove portion 50 may be employed. Both may be combined. In the first embodiment, the transparent conductive film of ITO or the like is employed.

### First Modification Example

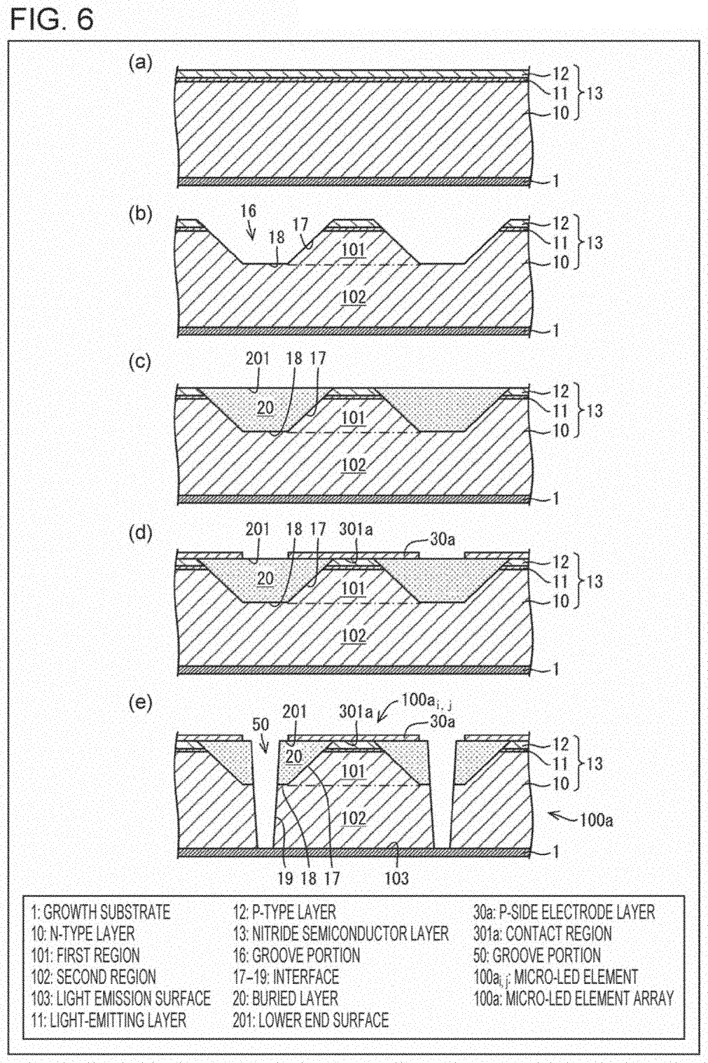

A configuration and a production method S1 of a micro-LED element 100a_{i,j} as a first modification example of the present invention will be described with reference to FIG. 6. FIGS. 6(a) to 6(e) are sectional views illustrating the micro-LED element 100a_{i,j} in each step of the production method S1 in the first modification example.

The micro-LED element 100a_{i,j} is obtained by removing the surface protection film 14 (that is, protective mask 15) used in the production method S1 illustrated in FIG. 2. In the first modification example, only differences of the configuration and the production method of the micro-LED element 100a_{i,j} from the configuration and the production method of the micro-LED element 100_{i,j} will be described.

For easy description, members having the same functions as those in the micro-LED element 100_{i,j} among members constituting the micro-LED element 100a_{i,j} are denoted by the same reference signs, and descriptions thereof will not be repeated. This is similarly applied to a second modification example and a third modification example described later.

A first deposition step S11 in a production method S1 in the first modification example is similar to the first deposition step S11 illustrated in FIG. 2. However, in the first deposition step S11 in the first modification example, a step of forming the surface protection film 14 is omitted.

In the first modification example, a first etching step S12 in the production method S1 is a step of forming the groove portion 16 by etching a portion of the nitride semiconductor layer 13, as illustrated in FIG. 6(b).

In the first modification example, a second deposition step S13 in the production method S1 is identical to the second deposition step S13 illustrated in FIG. 2.

In the first modification example, a polishing step S14 in the production method S1 is a step of flattening the surface by polishing the surfaces of the P-type layer 12 and the buried layer 20. In the polishing step S14 in the first modification example, for example, CMP may also be employed as the method for polishing the surface. In the production method S1 in the first modification example, the protective mask 15 is omitted. Thus, the protective mask removal step S15 included in the production method S1 illustrated in FIG. 2 is omitted. Thus, it is necessary to notice (1) a point that the film of the P-type layer 12 is thinned, and (2) a point that metal contamination may occur in the nitride semiconductor layer 13 by exposing the surface of the P-type layer 12 to a polishing liquid or a polishing pad. Film thinning of the P-type layer 12 may be handled by forming the P-type layer 12 to be thick in advance in the first deposition step S11. It is possible to suppress metal contamination to the minimum by enhancing cleaning after CMP.

A P-side electrode layer forming step S16 (see FIG. 6(d)) and a second etching step S17 (see FIG. 6(e)) included in the production method S1 in the first modification example are identical to the P-side electrode layer forming step S16 and the second etching step S17 illustrated in FIG. 2, respectively.

As a production method of producing an image display element using a micro-LED element array 100a configured by a plurality of the micro-LED elements 100a_{i,j}, the production method S2 illustrated in FIG. 4 may be applied.

### Second Modification Example

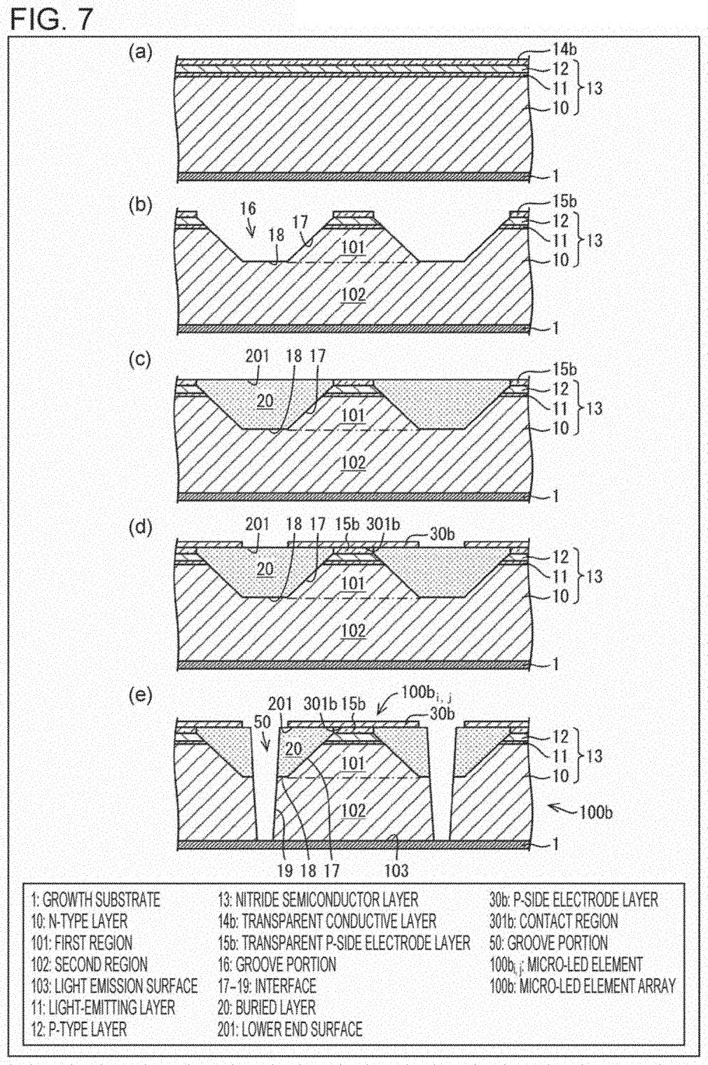

A configuration and a production method S1 of a micro-LED element 100b_{i,j} as a second modification example of the present invention will be described with reference to FIG. 7. FIGS. 7(a) to 7(e) are sectional views illustrating the micro-LED element 100b_{i,j} in each step of the production method S1 in the second modification example.

The micro-LED element 100b_{i,j} is obtained by using a transparent conductive layer 14b (that is, transparent P-side electrode layer 15b) instead of the surface protection film 14 (that is, protective mask 15) used in the production method S1 illustrated in FIG. 2.

A first deposition step S11 in a production method S1 in the second modification example is similar to the first deposition step S11 illustrated in FIG. 2. However, in the first deposition step S11 in the second modification example, the transparent conductive layer 14b is formed instead of forming the surface protection film 14 (see FIG. 7(a)). In the second modification example, activation annealing of the P-type layer 12 is performed before the transparent conductive layer 14b is formed. Examples of the material forming the transparent conductive layer 14b include indium-tin-oxide (ITO) and tin oxide (SnOₓ). The thickness of the transparent conductive layer 14b is preferably in a range of 40 nm to 500 nm.

A first etching step S12 in the production method S1 in the second modification example is similar to the first etching step S12 illustrated in FIG. 2 (see FIG. 7(b)). The first etching step S12 is performed, and thereby a transparent P-side electrode layer 15b being a remaining portion of the transparent conductive layer 14b remains on the surface of the P-type layer 12. As illustrated in FIG. 7(b), the groove portion 16 is formed by the first etching step S12.

A second deposition step S13 and a polishing step S14 included in the production method S1 in the second modification example are steps identical to the second deposition step S13 and the polishing step S14 illustrated in FIG. 2 (see FIG. 7(c)).

In the production method S1 illustrated in FIG. 2, the protective mask removal step S15 is performed after the polishing step S14. However, in the second modification example, a P-side electrode layer forming step S16 is performed without removing the transparent P-side electrode layer 15b itself.

A P-side electrode layer forming step S16 (see FIG. 7(d)) and a second etching step S17 (see FIG. 7(e)) included in the production method S1 in the first modification example are identical to the P-side electrode layer forming step S16 and the second etching step S17 illustrated in FIG. 2, respectively.

As a production method of producing an image display element using a micro-LED element array 100b configured by a plurality of the micro-LED elements 100b_{i,j}, the production method S2 illustrated in FIG. 4 may be applied.

### Second Example

A micro-LED element 100b_{i,j} as a second example of the present invention will be described below. The micro-LED element 100b_{i,j} in the second example has a configuration similar to that of the micro-LED element 100_{i,j} as the first example of the present invention and is different from the first example only that a transparent P-side electrode layer 15b is provided instead of the protective mask 15.

The light output of the micro-LED element 100b_{i,j} in the second example is improved by about 3% compared to the light output of the micro-LED element 100_{i,j} as the first example.

The inventor has estimated that the internal quantum efficiency of the micro-LED element 100b_{i,j} in the second example is equal to the internal quantum efficiency of the micro-LED element 100_{i,j} as the first example in a variation range, and thus the reason of improvement of the light output is improvement of the light extraction efficiency.

In the micro-LED element 100b_{i,j}, the transparent P-side electrode layer 15b is interposed between the P-side electrode layer 30 and the P-type layer 12. It is considered that, as a result, reflectivity at an interface between the P-side electrode layer 30 and the P-type layer 12 (that is, contact region 301b of the P-side electrode layer 30) is improved, and thus light absorbed by the P-side electrode layer 30 is reduced. The inventor has estimated that this is the reason of improving the light extraction efficiency.

As described above, in the micro-LED element 100b_{i,j}, it is possible to more improve the light output in comparison to the micro-LED element 100_{i,j}.

### Third Modification Example

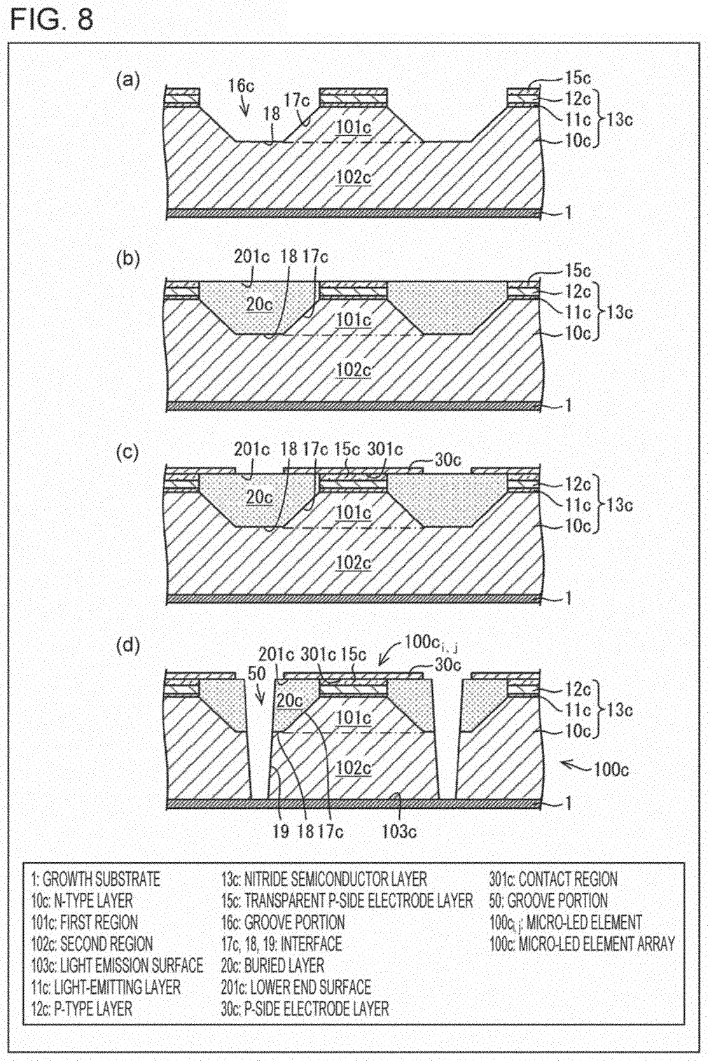

A configuration and a production method S1 of a micro-LED element 100c_{i,j} as a third modification example of the present invention will be described with reference to FIG. 8. FIGS. 8(a) to 8(e) are sectional views illustrating the micro-LED element 100c_{i,j} in each step of the production method S1 in the third modification example.

The micro-LED element 100c_{i,j} is configured to be similar to the micro-LED element 100b_{i,j} illustrated in FIG. 7 except for the shapes of a groove portion 16c and a buried layer 20c. In the third modification example, this point will be described.

The interface 17 provided in the micro-LED element 100b_{i,j} is formed to surround the side of the P-type layer 12, the side of the light-emitting layer 11, and the side of the first region 101 of the N-type layer 10. On the contrary, an interface 17c provided in the micro-LED element 100c_{i,j} is formed to surround only the side of a first region 101c.

A first deposition step S11 included in the production method S1 in the third modification example is identical to the first deposition step S11 included in the production method S1 in the second modification example. Thus, as illustrated in FIG. 7(a), the nitride semiconductor layer 13 and the transparent conductive layer 14b are deposited on the growth substrate 1 in this order. The members corresponding to the N-type layer 10, the light-emitting layer 11, the P-type layer 12, the nitride semiconductor layer 13, and the transparent conductive layer 14b in the micro-LED element 100b_{i,j} are referred to as an N-type layer 10c, a light-emitting layer 11c, a P-type layer 12c, a nitride semiconductor layer 13c, and a transparent conductive layer 14c in the third modification example, respectively. The members corresponding to the transparent P-side electrode layer 15b, the interface 17, and the buried layer 20 in the micro-LED element 100b_{i,j} are referred to as a transparent P-side electrode layer 15c, the interface 17c, and a buried layer 20c, in the third modification example, respectively.

A first etching step S12 in the production method S1 in the third modification example is performed using the same method as the method in the first etching step S12 illustrated in FIG. 7. However, as illustrated in FIG. 8(a), the shape of the groove portion 16c formed in the first etching step S12 is different from the shape of the groove portion 16 illustrated in FIG. 7(b). Specifically, the groove portion 16 is formed such that an angle between the entire portion (portion corresponding to the first region 101, portion corresponding to the light-emitting layer 11, and portion corresponding to the P-type layer 12) of the side wall and the surface of the light-emitting layer 11 is 45 degrees. On the contrary, the groove portion 16c is formed such that an angle between a portion of the side wall corresponding to the first region 101c and the surface of the light-emitting layer 11c is 45 degrees, and an angle between a portion corresponding to the light-emitting layer 11c and a portion corresponding to the P-type layer 12c in the side wall, and the surface of the light-emitting layer 11c is about 90 degrees. Thus, the interface 17c at which the angle θ₁ is 45 degrees surrounds only the first region 101c.

Since the groove portion 16c is configured in the above-described manner, in the micro-LED element 100c_{i,j}, it is possible to increase the area of the light-emitting layer 11c and the area of the P-type layer 12c in comparison to the micro-LED element 100b_{i,j}.

A second deposition step S13 and a polishing step S14 included in the production method S1 in the third modification example are steps identical to the second deposition step S13 and the polishing step S14 illustrated in FIG. 7 (see FIG. 8(b)).

Also in the production method S1 in the third modification example, the transparent P-side electrode layer 15b is not removed.

A P-side electrode layer forming step S16 included in the production method S1 in the third modification example is a step identical to the P-side electrode layer forming step S16 illustrated in FIG. 7 (see FIG. 8(c)).

A second etching step S17 in the production method S1 in the third modification example is a step identical to the second etching step S17 illustrated in FIG. 7 (see FIG. 8(d)).

As a production method of producing an image display element using a micro-LED element array 100c configured by a plurality of the micro-LED elements 100c_{i,j}, the production method S2 illustrated in FIG. 4 may be applied.

### Third Example

A micro-LED element 100c_{i,j} as a third example of the present invention will be described below. The micro-LED element 100c_{i,j} in the third example is based on the configuration of the micro-LED element 100_{i,j} as the first example of the present invention. The micro-LED element 100c_{i,j} in the third example is different from the micro-LED element 100_{i,j} as the first example in that the transparent P-side electrode layer 15c is provided instead of the protective mask 15, and the interface 17c surrounds only the side of the first region 101c.

The light output of the micro-LED element 100c_{i,j} in the third example is improved by about 50% compared to the light output of the micro-LED element 100 in which the interface 17 is omitted. The internal quantum efficiency of the micro-LED element 100c_{i,j} in the third example exceeds the internal quantum efficiency (70%) of the micro-LED element 100 in which the interface 17c is omitted and is 73%. The light extraction efficiency of the micro-LED element 100c_{i,j} in the third example is 25% and is largely improved compared to the light extraction efficiency (15%) of the micro-LED element 100 in which the interface 17c is omitted.

As described above, an effect of improving the light extraction efficiency is exhibited so long as the interface 17c is formed in a region surrounding at least only the side of the first region 101c. Thus, as in the micro-LED element 100_{i,j}, the micro-LED element 100a_{i,j}, and the micro-LED element 100b_{i,j}, the interface 17 may be formed in the region surrounding the sides of the first region 101, the light-emitting layer 11, and the P-type layer 12. As in the micro-LED element 100c_{i,j} the interface 17c may be formed only in the region surrounding only the side of the first region 101c.

### Second Embodiment

(Configuration of Micro-LED Element 100d_{i,j})

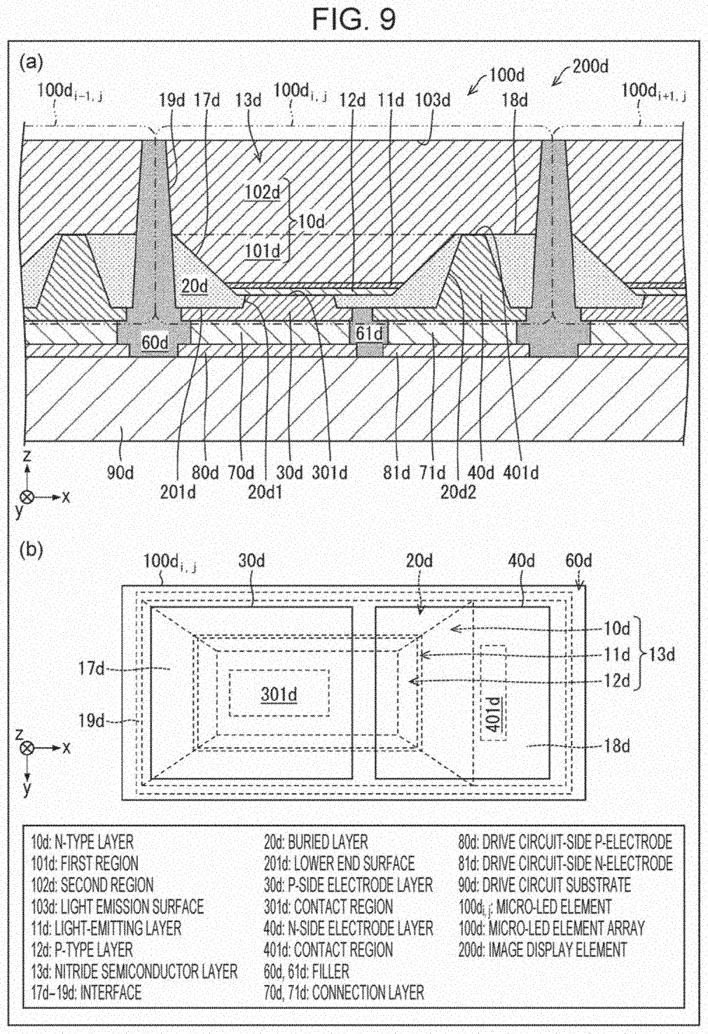

An image display element 200d in which a micro-LED element 100d_{i,j} according to a second embodiment of the present invention is mounted as the light source will be described with reference to FIGS. 9 to 13.

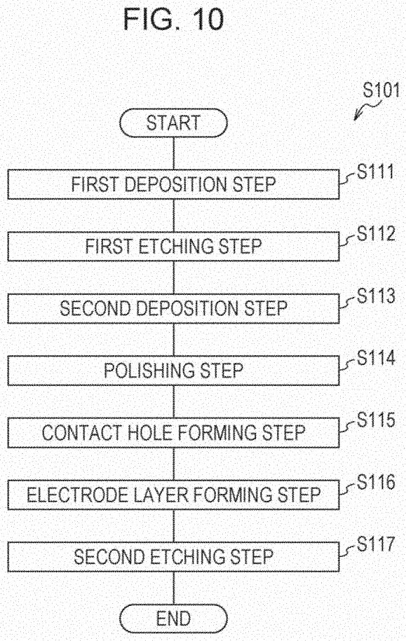

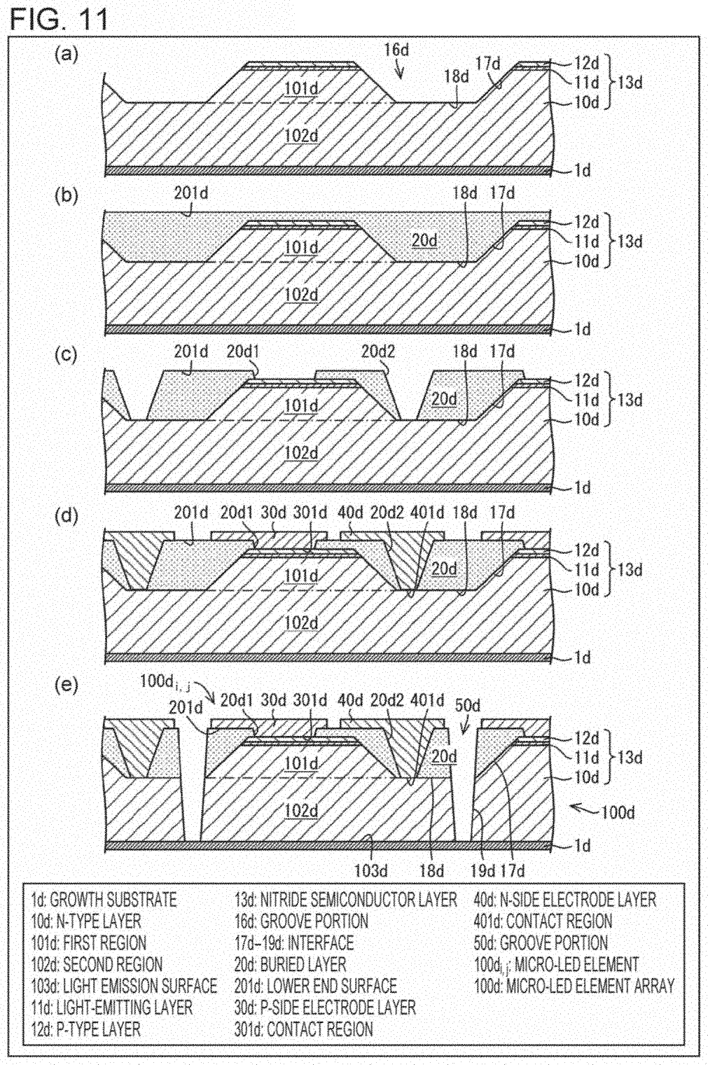

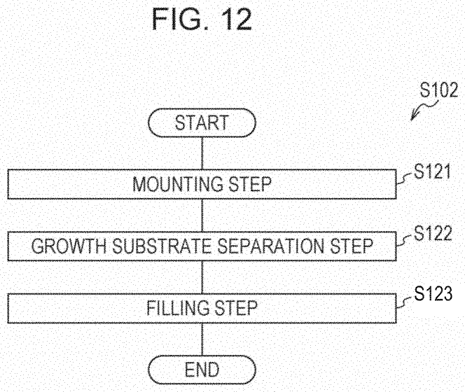

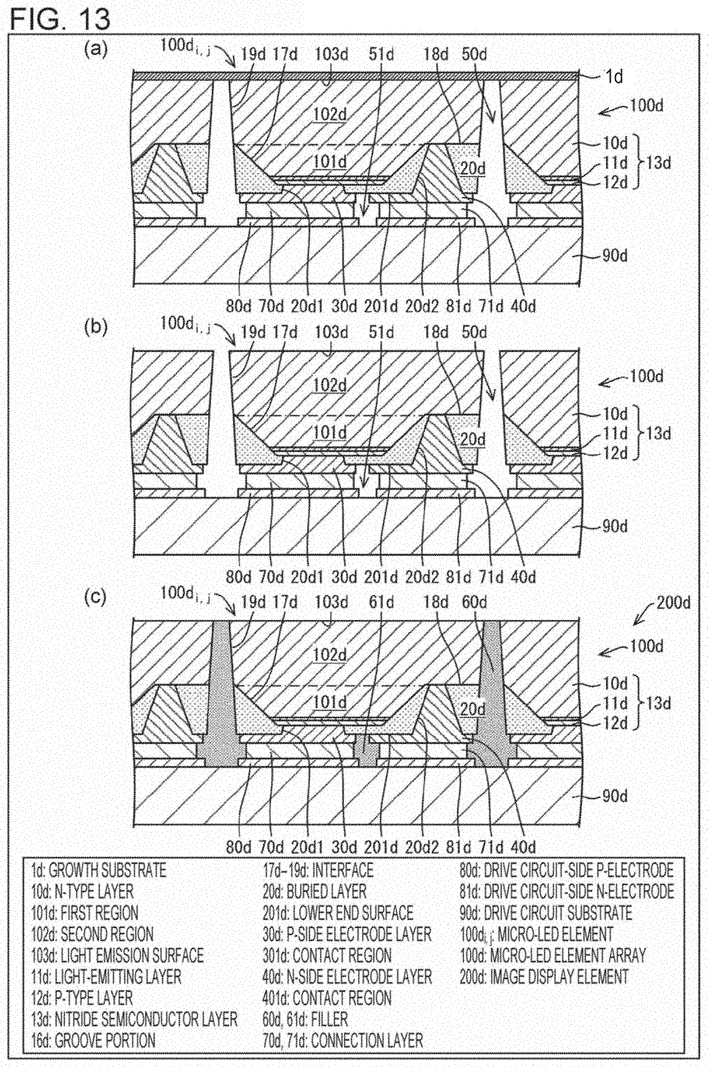

FIG. 9(a) is a sectional view illustrating the image display element 200d including a plurality of the micro-LED elements 100d_{i,j}. FIG. 9(b) is a plan view in a case where the micro-LED element 100d_{i,j} is viewed from a P-side electrode layer 30d and N-side electrode layer 40d side. FIG. 10 is a flowchart illustrating a production method S101 of the micro-LED element 100d_{i,j}. FIGS. 11(a) to 11(e) are sectional views illustrating the micro-LED element 100d_{i,j} in each step of the production method S101. FIG. 12 is a flowchart illustrating a production method S102 of the image display element 200d. FIGS. 13(a) to 13(c) are sectional views illustrating the image display element 200d in each step of the production method S102. A coordinate system illustrated in FIG. 9 is defined to be similar to the coordinate system illustrated in FIG. 1.

Each member constituting the micro-LED element 100d_{i,j} is denoted by a reference sign obtained by adding an alphabetical letter “d” to the end of the reference sign of each member constituting the micro-LED element 100_{i,j}=according to the first embodiment. For example, an N-type layer 10d, a light-emitting layer 11d, a P-type layer 12d, and a nitride semiconductor layer 13d in the micro-LED element 100d_{i,j} correspond to the N-type layer 10, the light-emitting layer 11, the P-type layer 12, and the nitride semiconductor layer 13 in the micro-LED element 100_{i,j}, respectively. This is similarly applied to other members. In the second embodiment, descriptions of members having the same function as those of the members described in the first embodiment will not be repeated.

As illustrated in FIG. 9, the micro-LED element 100d_{i,j} includes the nitride semiconductor layer 13d, a buried layer 20d, a P-side electrode layer 30d, and an N-side electrode layer 40d. The nitride semiconductor layer 13d includes the N-type layer 10d, the light-emitting layer 11d, and the P-type layer 12d. In a case where the nitride semiconductor layer 13d is viewed from a light emission surface side, the N-type layer 10d, the light-emitting layer 11d, and the P-type layer 12d are stacked in this order.

The N-type layer 10d includes a first region 101d and a second region 102. Sides of the first region 101d, the light-emitting layer 11d, and the P-type layer 12d are surrounded by an interface 17d. An angle θ₁ between the interface 17d and the surface of the light-emitting layer 11d is 45 degrees (prescribed first angle described in claims) in the second embodiment. The side of the second region 102d is surrounded by an interface 19d. An angle θ₂ between the interface 19d and the surface of the light-emitting layer 11d is greater than 45 degrees and is 80 degrees (prescribed second angle described in claims) in the second embodiment. The interface 17d and the interface 19d correspond to the first interface and the second interface described in claims, respectively.

The P-side electrode layer 30d is formed on a P-type layer 12d side (lower side) of the nitride semiconductor layer 13d and is in contact with the P-type layer 12d.

The nitride semiconductor layer 13d further includes an interface 18d connecting the interface 17d and the interface 19d. The interface 18d is a third interface described in claims. In a case where the micro-LED element 100d_{i,j} is viewed from the bottom in plan view, the interface 18d is formed in a region other than a region in which the P-side electrode layer 30d is formed. The interface 18d and the surface of the light-emitting layer 11d are parallel to each other in the second embodiment, but is not necessarily limited to being parallel.

In the buried layer 20d deposited on the outer side of the interface 17d surrounding the first region 101d, the N-side electrode layer 40d is formed in the region other than the region in which the P-side electrode layer 30d is formed. In the N-side electrode layer 40d, a contact region 401d is exposed from the buried layer 20d at a portion of the interface 18d, and the contact region 401d is in contact with the second region 102d.

Similar to a case of the image display element 200 illustrated in FIG. 1, the image display element 200d includes a drive circuit substrate 90d and a plurality of the micro-LED elements 100d_{i,j} which are stacked on the surface of the drive circuit substrate 90d in a two-dimensional array. The plurality of the micro-LED elements 100d_{i,j} arranged in a two-dimensional array is referred to as a micro-LED element array 100d.

In each of the plurality of the micro-LED elements 100d_{i,j}, the P-side electrode layer 30d is connected to a drive circuit-side P-electrode 80d with a connection layer 70d, and the N-side electrode layer 40d is connected to a drive circuit-side N-electrode 81d with a connection layer 71d. When a drive current is supplied from the drive circuit of the drive circuit substrate 90d to the plurality of the micro-LED elements 100d_{i,j}, each of the plurality of the micro-LED elements 100d_{i,j} emits light. Intensity of the light emitted by the micro-LED element 100_{i,j} is determined in accordance with the magnitude of the drive current. The micro-LED element 100d_{i,j} may further include a wavelength conversion layer, a light diffusing layer, a color filter, or the like disposed on a light emission side (side from the light emission surface of the second region 102 in the z-axis positive direction). However, since the wavelength conversion layer, the light diffusing layer, the color filter, and the like have no direct relation with the micro-LED element 100d_{i,j}, the wavelength conversion layer, the light diffusing layer, the color filter, and the like are not illustrated.

As described above, the entire circumference of the sides of the first region 101d, the light-emitting layer 11d, and the P-type layer 12d in the nitride semiconductor layer 13d is covered by the interface 17d. In plan view, the micro-LED element 100d_{i,j} is formed to have a rectangular outline. In this case, the interface 17d is configured by four planes. The four planes are arranged to form side surfaces of a truncated quadrangular pyramid having a rectangular bottom surface.

In plan view, the outline of the micro-LED element 100d_{i,j} may be another polygon (for example, regular hexagon), a circle, or an ellipse instead of a rectangle (including a square). This is identical to the micro-LED element 100_{i,j}. A point that the angle θ₁ and the angle θ₂ may be respectively in the range of the angle θ₁±10 degrees and in the range of the angle θ₂±10 degrees is also identical to the micro-LED element 100_{i,j}. A point that the angle θ₂ is preferably substantially perpendicular is identical to the micro-LED element 100_{i,j}.

As illustrated in FIG. 9(a), the outer side of the interface 17d and a lower portion of the P-type layer 12 are covered by the buried layer 20d. A lower end surface 201d of the buried layer 20d is polished to be flat along an xy plane (see a polishing step S114 illustrated in FIG. 10). That is, the lower end surface 201d has high surface flatness.

The buried layer 20d is preferably formed of a material which is transparent to visible light and has a refractive index smaller than a refractive index of a material forming the nitride semiconductor layer 13d. Examples of the preferable material forming the buried layer 20d include SiO₂.

Since the buried layer 20d flattens the lower portion of the micro-LED element 100d_{i,j}, it is possible to dispose the P-side electrode layer 30d and the N-side electrode layer 40d in the substantially entirety of the lower surface of the micro-LED element 100d and to increase an electrode area to the maximum. The P-side electrode layer 30d and the N-side electrode layer 40d have a flat surface succeeding the surface flatness of the buried layer 20d. It is possible to realize a wide flat electrode surface, and thus it is possible to easily make a connection with the drive circuit substrate 90d.

### Fourth Example

A micro-LED element 100d_{i,j} as a fourth example of the present invention will be described below. The micro-LED element 100d_{i,j} in the fourth example is obtained by employing a configuration as follows in the micro-LED element 100d_{i,j} illustrated in FIG. 9.
Outline in plan view: rectangle in which the length of the short side is 7 μm, and the length of the long side is 14 μm
tₚ=100 nm
t_{mqw}=70 nm
tₙ₁=1500 nm
θ₁=45 degrees

A micro-LED element in which the interface 17d is removed from the configuration of the micro-LED element 100d_{i,j} in the fourth example is used as a second comparative example.

In a state where the same drive current is supplied to the micro-LED elements, light outputs of the micro-LED element 100d_{i,j} in the fourth example and the micro-LED element in the second comparative example are measured. As a result, the light output of the micro-LED element 100d_{i,j} in the fourth example is 220% of the light output of the micro-LED element in the second comparative example.

The inventor of the present application has estimated that the reason that the light output of the micro-LED element 100d_{i,j} is significantly increased compared to the micro-LED element in the second comparative example is similar to the reason that the light output in the micro-LED element 100_{i,j} is increased.

In the micro-LED element 100_{i,j}, the area of the light-emitting layer 11d is much smaller than the area of the micro-LED element 100d_{i,j} In the fourth example, a ratio of the area of the light-emitting layer 11 to the area of the micro-LED element 100_{i,j} is

{7000−(70+1500)*2}*{7000−(70+1500)*2−1000}/(7000*13000)=0.418,

and this is about 42%. Regardless of whether or not the interface 17d is provided, a region for bringing the N-side electrode layer 40d in contact with the N-type layer 10d is required. In the above calculation, such a region is excluded.

Further, since the peripheral portion of the light-emitting layer 11d is damaged by dry etching of the nitride semiconductor layer 13d, it is considered that the area of the light-emitting layer 11d, which effectively contributes to light emission is much smaller. Since the damaged portion consumes a current without emitting light, it is estimated that the light emission efficiency is decreased. Such an effect appears as a decrease in internal quantum efficiency of the micro-LED element 100d_{i,j}. The internal quantum efficiency and the light extraction efficiency are separated from each other using data of current dependency of the external quantum efficiency, and the internal quantum efficiency is evaluated. As a result, the internal quantum efficiency of the micro-LED element 100d_{i,j} in the fourth example is 69.5%, and the internal quantum efficiency of the micro-LED element in the second comparative example is 71%, and there is no large difference in internal quantum efficiency between the fourth example and the second comparative example. Thus, it is understood that improvement more than twice in light emission efficiency is mainly caused by improvement of the light extraction efficiency.

The area of the light-emitting layer 11d is about 1/2.4 of the area of the light-emitting layer in the micro-LED element in the second comparative example. Normally, in a case where the area of the light-emitting layer 11d is reduced, the internal quantum efficiency is to be largely decreased. However, it is estimated that the reason that the internal quantum efficiency of the micro-LED element 100d_{i,j} in the fourth example is not largely deteriorated in comparison to the internal quantum efficiency of the micro-LED element in the second comparative example is that significant reduction in damage on the light-emitting layer 11d is possible.

In this structure, the area of the P-type layer 12d is much smaller than the area of the micro-LED element 100d_{i,j}. Regardless of this, the sum of the area of the P-side electrode layer 30d and the area of the N-side electrode layer 40d are substantially equal to the area of the micro-LED element 100d_{i,j}, and the surfaces of the P-side electrode layer 30d and the N-side electrode layer 40d are flat. Regardless of the small area of the P-type layer 12d, it is possible to form the P-side electrode layer 30d and the N-side electrode layer 40d having a wide area and a flat surface. As described above, the P-side electrode layer 30d and the N-side electrode layer 40d in the micro-LED element 100d_{i,j} are stably and firmly connected to the drive circuit-side P-electrode 80d and the drive circuit-side N-electrode 81d, by using the connection layer 70d and the connection layer 71d, respectively. Thus, it is possible to reduce defects occurring, for example, in a manner that the micro-LED element 100d_{i,j} is pulled by a growth substrate 1d and thus is chipped off or that the micro-LED element 100_{i,j} is inclined by a mechanical impact, when the growth substrate 1d is separated from the N-type layer 10d in a growth substrate separation step S122 (see FIG. 12) described later.

(Production Method S101 of Micro-LED Element 100d_{i,j})

Next, a production method S101 as an example of a production method of the micro-LED element 100d_{i,j} will be described with reference to FIGS. 10 and 11.

As illustrated in FIG. 10, the production method S101 includes a first deposition step S111, a first etching step S112, a second deposition step S113, a polishing step S114, a contact hole forming step S115, an electrode layer forming step S116, and a second etching step S117.

The first deposition step S111 is similar to the first deposition step S11 illustrated in FIG. 2 and is a step of obtaining the nitride semiconductor layer 13d by depositing the N-type layer 10d, the light-emitting layer 11d, and the P-type layer 12d on the growth substrate 1d in this order. The growth substrate 1d is configured in a manner similar to the growth substrate 1 used in the production method S1. The nitride semiconductor layer 13d configured by the N-type layer 10d, the light-emitting layer 11d, and the P-type layer 12d is configured similar to the nitride semiconductor layer 13 configured by the N-type layer 10, the light-emitting layer 11, and the P-type layer 12 used in the production method S1.

As illustrated in FIG. 11(a), the first etching step S112 is a step of forming the groove portion 16d by etching a portion of the nitride semiconductor layer 13d and providing the first region 101d having an etched side and the second region 102d being a region other than the first region 101d, in the N-type layer 10d. The first etching step S112 is performed similar to the first etching step S12 in the production method S1.

The second deposition step S113 is a step of depositing the buried layer 20d on the groove portion 16d and is performed similar to the second deposition step S13 in the production method S1.

The polishing step S114 is a step of polishing the surface of the buried layer 20d to be flat, by polishing the surface of the buried layer 20d. As a method of polishing the buried layer 20d, for example, a CMP (chemical mechanical polishing) method may be employed. Here, the polishing degree of CMP is adjusted such that a portion of the buried layer 20d remains on the P-type layer 12d to have a predetermined film thickness. The film thickness of the buried layer 20d remaining on the P-type layer 12d is about 50 nm to about 1000 nm.

The second deposition step S113 and the polishing step S114 are performed, and thereby, as illustrated in FIG. 11(b), a structure in which the surface of the buried layer 20d is polished to be flat is obtained.

As illustrated in FIG. 11(c), the contact hole forming step S115 is a step of forming a contact hole 20dl in the buried layer 20d deposited on the P-type layer 12 and forming a contact hole 20d2 in the buried layer 20d deposited on the groove portion 16d.

As illustrated in FIG. 11(d), the electrode layer forming step S116 is a step of forming the P-side electrode layer 30d in the contact hole 20d1 and on the surface of the buried layer 20d and forming the N-side electrode layer 40d in the contact hole 20d2 and on the surface of the buried layer 20d. In a case where an aspect ratio of the contact hole 20d2 is high, a tungsten plug may be buried in the contact hole 20d2. In a case where the aspect ratio is equal to or greater than 1, the tungsten plug is preferably buried. In a case where the aspect ratio is smaller than 1, it is possible to form the N-side electrode layer 40d by using a general thin film deposition method.

As illustrated in FIG. 11(e), the second etching step S117 is a step of exposing a portion of the growth substrate 1d by performing dry etching on portions of the buried layer 20d and the second region 102d. A groove portion 50d is formed by performing the second etching step S117. The second etching step S117 is performed similar to the second etching step S17 in the production method S1.

With the above steps, the nitride semiconductor layer 13d and the buried layer 20d formed on one growth substrate 1d are divided into a plurality of the micro-LED elements 100d_{i,j} arranged in a two-dimensional array. That is, a micro-LED element array 100d is obtained.

(Production Method S102 of Image Display Element 200d)

Next, a production method S102 being an example of a production method of the image display element 200d using the micro-LED element array 100d including the plurality of the micro-LED elements 100d_{i,j} will be described with reference to FIGS. 12 and 13.

Before the production method S102, the drive circuit substrate 90d on which the drive circuit configured to drive each micro-LED element 100d_{i,j} is mounted is prepared. The drive circuit-side P-electrode 80d and the drive circuit-side N-electrode 81d for causing a current to flow in the micro-LED element 100d_{i,j} are provided on the surface of the drive circuit substrate 90d. Various circuits for selecting each micro-LED element 100d_{i,j} and causing a prescribed current to flow are provided in the drive circuit substrate 90d, but are not directly related to the present invention. Thus, here, descriptions thereof will be omitted. The drive circuit substrate 90d may be silicon LSI itself or may include a TFT formed on glass or a film.

As illustrated in FIG. 12, the production method S102 includes a mounting step S121, a growth substrate separation step S122, and a filling step S123.

As illustrated in FIG. 13(a), the mounting step S121 is a step of mounting the micro-LED element array 100d on the drive circuit substrate 90d. In the mounting step S21, the connection layer 70d is formed on the drive circuit-side P-electrode 80d, and the connection layer 71d is formed on the drive circuit-side N-electrode 81d. The micro-LED element array 100d is bonded thereon, and thus the P-side electrode layer 30d is electrically connected to the drive circuit-side P-electrode 80d through the connection layer 70d, and the N-side electrode layer 40d is electrically connected to the drive circuit-side N-electrode 81d through the connection layer 71d.

In the micro-LED element 100d_{i,j} the P-side electrode layer 30d and the N-side electrode layer 40d are spaced from each other. Similarly, the drive circuit-side P-electrode 80d and the drive circuit-side N-electrode 81d are spaced from each other, and the connection layer 70d and the connection layer 71d are spaced from each other. As a result, a gap 51d is formed between (the P-side electrode layer 30d, the connection layer 70d, and the drive circuit-side P-electrode 80d) and (the N-side electrode layer 40d, the connection layer 71d, and the drive circuit-side N-electrode 81d).

As illustrated in FIG. 13(b), the growth substrate separation step S122 is a step of separating the growth substrate 1d from the micro-LED element array 100d by a laser separation method and is performed similar to the growth substrate separation step S22 in the production method S2.

As illustrated in FIG. 13(c), the filling step S123 is a step of filling the groove portion 50d with a filler 60d and filling the gap 51d with a filler 61d and is performed similar to the filling step S23 in the production method S2.

### Third Embodiment

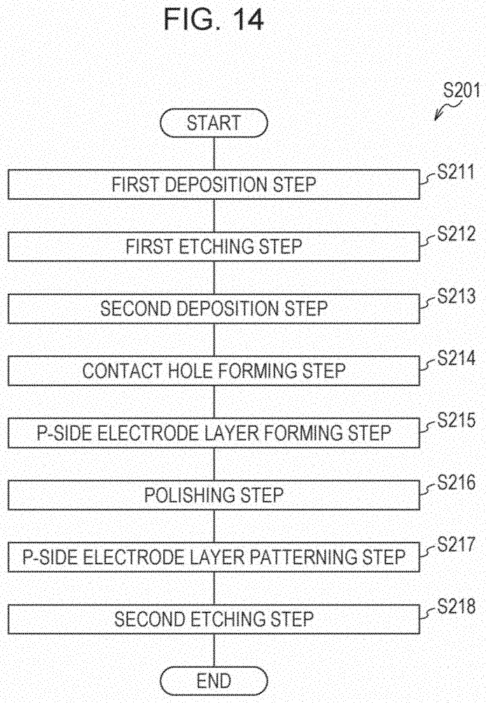

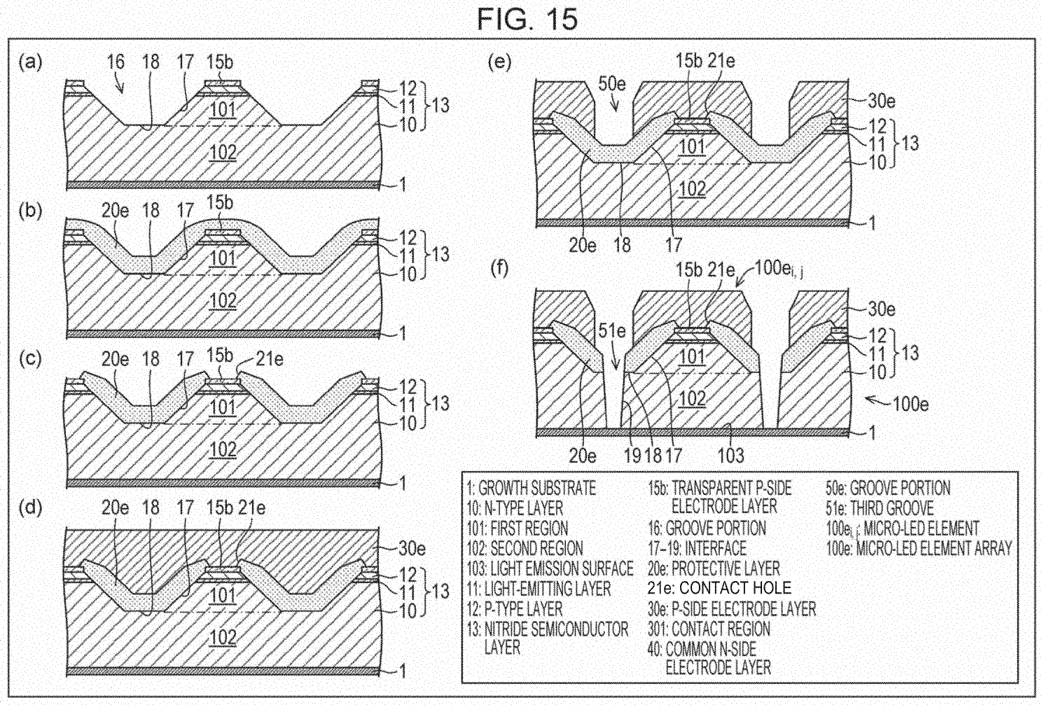

A micro-LED element 100e_{i,j} according to a third embodiment of the present invention will be described below with reference to FIGS. 14 and 15.

FIG. 14 is a flowchart illustrating a production method S201 of the micro-LED element 100e_{i,j}. FIGS. 15(a) to 15(f) are sectional views illustrating the micro-LED element 100e_{i,j} in each step of the production method S201.

For easy description, members having the same functions as those described in the second modification example of the present invention are denoted by the same reference signs, and descriptions thereof will not be repeated.

For example, an N-type layer 10, a light-emitting layer 11, a P-type layer 12, a nitride semiconductor layer 13, and a transparent P-side electrode layer 15b in the micro-LED element 100e_{i,j} are identical to the N-type layer 10, the light-emitting layer 11, the P-type layer 12, the nitride semiconductor layer 13, and the transparent P-side electrode layer 15b in the micro-LED element 100b_{i,j}. A protective layer 20e and a P-side electrode layer 30e in the micro-LED element 100e_{i,j} correspond to the buried layer 20 and the P-side electrode layer 30b in the micro-LED element 100b_{i,j}, respectively.

In the micro-LED element 100b_{i,j} as the second modification example of the present invention, since the surface of the buried layer 20 is flattened, at least the surface of the P-side electrode layer 30b is flattened, and thus a firm connection with the drive circuit substrate 90 is realized. In the micro-LED element 100e_{i,j} the protective layer 20e having a substantially uniform film thickness is used instead of the buried layer 20, and an effect similar to that in the micro-LED element 100_{i,j} is obtained by flattening the surface of the P-side electrode layer 30e in this state. In the third embodiment, the protective layer 20e and the P-side electrode layer 30e will be mainly described.

As illustrated in FIG. 14, the production method S201 includes a first deposition step S211, a first etching step S212, a second deposition step S213, a contact hole forming step S214, a P-side electrode layer forming step S215, a polishing step S216, a P-side electrode layer patterning step S217, and a second etching step S218.

The first deposition step S211 and the first etching step S212 are identical to the first deposition step S11 and the first etching step S12 performed in the second modification example of the present invention, respectively. Thus, a structure illustrated in FIG. 15(a) is identical to the structure illustrated in FIG. 7(b).

As illustrated in FIG. 15(b), the second deposition step S213 is a step of depositing the protective layer 20e having a substantially uniform film thickness, on the nitride semiconductor layer 13. The film thickness of the protective layer 20e is about 100 nm to 1500 nm. At a step at which the protective layer 20e is formed, an unevenness corresponding to the shape of the groove portion 16 is provided in the surface of the protective layer 20e.

As illustrated in FIG. 15(c), the contact hole forming step S214 is a step of forming a contact hole 21e in a region of the protective layer 20e on the transparent P-side electrode layer 15b.

The P-side electrode layer forming step S215 is a step of forming the P-side electrode layer 30e by depositing a conductor on the surface of the protective layer 20e and on the surface of the transparent P-side electrode layer 15b exposed from the protective layer 20e. As the conductor used here, nickel, aluminum, titanium, titanium nitride, aluminum copper alloys, or the like may be employed. The P-side electrode layer 30e is preferably a multilayer film obtained by sequentially depositing some of the above conductors.

The polishing step S216 is a step of flattening the surface of the P-side electrode layer 30e by polishing the surface of the P-side electrode layer 30e. A structure illustrated in FIG. 15(d) is obtained by performing the P-side electrode layer forming step S215 and the polishing step S216. The polishing step S216 may be performed similar to the polishing step S14 illustrated in FIG. 2.

In the third embodiment, a flow film formation method may be employed in the P-side electrode layer forming step S215, and the surface of the P-side electrode layer 30e may be flattened in the middle of forming the P-side electrode layer 30e. In this case, a step of flattening the surface of the P-side electrode layer 30e is included in the P-side electrode layer forming step S215.

As illustrated in FIG. 15(e), the P-side electrode layer patterning step S217 is a step of patterning the P-side electrode layer 30e in a desired shape by etching a portion of the P-side electrode layer 30e. A groove portion 50e is formed by performing the P-side electrode layer patterning step S217, and P-side electrode layers 30e adjacent to each other are spaced from each other.

As illustrated in FIG. 15(f), the second etching step S218 is a step of making the groove portion 50e deeper and exposing a portion of the growth substrate 1, by etching portions of the protective layer 20e and the second region 102.

The second etching step S218 may be performed similar to the second etching step S17 illustrated in FIG. 7.

With the above steps, the nitride semiconductor layer 13 and the protective layer 20e formed on one growth substrate 1 are divided into a plurality of the micro-LED elements 100e_{i,j} arranged in a two-dimensional array. That is, a micro-LED element array 100e is obtained.

The light output of the micro-LED element 100e_{i,j} is substantially equal to the light output of the micro-LED element 100b_{i,j} as the second modification example of the present invention. That is, the micro-LED element 100e_{i,j} exhibits an effect of improving the light extraction efficiency, similar to the micro-LED element 100b_{i,j}.

In the third embodiment, detailed descriptions of the production method of the image display element will not be repeated. However, it is possible to produce the image display element in which the common N-side electrode layer 40 is stacked on the light emission surface 103, by performing the production method S2 illustrated in FIG. 4 using the micro-LED element array 100e and the drive circuit substrate 90.

### APPENDIX

Hitherto, the embodiments of the present invention are described. It should be noted that the above-described embodiments are examples, and various modifications can be made to a combination of components and processes, and it is understood by those skilled in the art that the various modifications are within the scope of the present invention.

The micro-LED element, the micro-LED element array, and the image display element according to the embodiments of the present invention can be suitably used for, for example, a projector, a head-up display, a head-mounted display, and a wearable terminal.

### CONCLUSION

According to Aspect 1 of the present invention, the micro-LED elements 100_{i,j}, 100a_{i,j}, 100b_{i,j}, 100c_{i,j}, 100d_{i,j}, and 100e_{i,j} include the nitride semiconductor layers 13, 13c, and 13d in which the N-type layers 10, 10c, and 10d, the light-emitting layers 11, 11c, and 11d, and the P-type layers 12, 12c, and 12d are stacked in this order when viewed from the light emission surfaces 103, 103c, and 103d side, and the P-side electrode layers 30, 30a, 30b, 30c, 30d, and 30e formed on the P-type layers 12, 12c, and 12d side.

The N-type layers 10, 10c, and 10d include the first regions 101, 101c, and 101d in contact with the light-emitting layers 11, 11c, and 11d and the second regions 102, 102c, and 102d including the light emission surfaces 103, 103c, and 103d. The angle θ₁ between the first interface (interfaces 17, 17c, and 17d) surrounding at least the sides of the first regions 101, 101c, and 101d and the light-emitting layers 11, 11c, and 11d in the nitride semiconductor layers 13, 13c, and 13d is the prescribed first angle (for example, θ₁=45 degrees) at which light propagating in the direction (for example, x-axis direction or y-axis direction) toward the light-emitting layers 11, 11c, and 11d is reflected in the direction (z-axis positive direction) toward the light emission surfaces 103, 103c, and 103d. The angle θ₂ between the second interface (interfaces 19 and 19d) surrounding the sides of the second regions 102, 102c, and 102d and the light-emitting layers 11, 11c, and 11d in the nitride semiconductor layers 13, 13c, and 13d is the prescribed second angle larger than the first angle (for example, 45 degrees).

According to the above configuration, at the first interface (interfaces 17, 17c, and 17d), the light propagating in the direction toward the light-emitting layers 11, 11c, and 11d is reflected in the direction toward the light emission surfaces 103, 103c, and 103d. Thus, the micro-LED elements 100_{i,j}, 100a_{i,j}, 100b_{i,j}, 100c_{i,j}, 100d_{i,j}, and 100e_{i,j} exhibit the effect of improving the light extraction efficiency compared to the micro-LED element in which the first interface (interfaces 17, 17c, and 17d) is not provided. In other words, in the micro-LED elements 100_{i,j}, 100a_{i,j}, 100b_{i,j}, 100c_{i,j}, 100d_{i,j}, and 100e_{i,j}, it is possible to suppress decrease of light emission efficiency in comparison to the micro-LED element in the related art, even if the size of the micro-LED element is reduced.

According to Aspect 2 of the present invention, in the micro-LED elements 100_{i,j}, 100a_{i,j}, 100b_{i,j}, 100c_{i,j}, 100d_{i,j}, and 100e_{i,j}, in Aspect 1, preferably, the first angle is an angle in the predetermined range centering on 45 degrees (for example, θ₁ is in a range of 45±10 degrees).

According to the above configuration, in the micro-LED elements 100_{i,j}, 100a_{i,j}, 100b_{i,j}, 100c_{i,j}, 100d_{i,j}, and 100e_{i,j}, it is possible to reliably suppress decrease of light emission efficiency in comparison to the micro-LED element in the related art, even if the size of the micro-LED element is reduced. In a case where etching for forming the first interface (interfaces 17, 17c, and 17d) is performed, fluctuation of the angle θ₁ due to the precision of etching is estimated to be about ±10 degrees. Thus, the angle θ₁ in the micro-LED elements 100_{i,j}, 100a_{i,j}, 100b_{i,j}, 100c_{i,j}, 100d_{i,j} and 100e_{i,j} produced in practice is not limited to the angle θ₁ being the prescribed angle and may be an angle in a range of the angle θ₁±10 degrees. The above-described fluctuation of the angle θ8 may change depending on the etching method employed in the first etching step.

According to Aspect 3 of the present invention, in the micro-LED elements 100_{i,j}, 100a_{i,j}, 100b_{i,j}, 100c_{i,j}, 100d_{i,j}, and 100e_{i,j}, in Aspect 1, preferably, the first angle is an angle in the range of 35 degrees to 55 degrees.

According to the above configuration, in the micro-LED elements 100_{i,j}, 100a_{i,j}, 100b_{i,j}, 100c_{i,j}, 100d_{i,j}, and 100e_{i,j}, it is possible to reliably suppress decrease of light emission efficiency in comparison to the micro-LED element in the related art, even if the size of the micro-LED element is reduced.

According to Aspect 4 of the present invention, in the micro-LED elements 100_{i,j}, 100a_{i,j}, 100b_{i,j}, 100c_{i,j}, 100d_{i,j}, and 100e_{i,j}, in any one of Aspects 1 to 3, preferably, the thickness tₙ₁ of the first regions 101, 101c, and 101d is thicker than the thickness tₚ of the P-type layers 12, 12c, and 12d.

According to the above configuration, the first interface (interfaces 17, 17c, and 17d) are formed in the sufficiently wide region in the direction (z-axis direction) from the light-emitting layer toward the light emission surfaces 103, 103c, and 103d. Therefore, at the first interface (interfaces 17, 17c, and 17d), in addition to the light propagating in the direction toward the light-emitting layers 11, 11c, and 11d, light propagating in a direction having an elevation angle from the light-emitting layers 11, 11c, and 11d toward z-axis positive direction side may be reflected in the direction toward the light emission surfaces 103, 103c, and 103d. Thus, in the micro-LED elements 100_{i,j}, 100a_{i,j}, 100b_{i,j}, 100c_{i,j}, 100d_{i,j}, and 100e_{i,j}, it is possible to more reliably suppress decrease of light emission efficiency in comparison to the micro-LED element in the related art, even if the size of the micro-LED element is reduced.

According to Aspect 5 of the present invention, in the micro-LED elements 100_{i,j}, 100a_{i,j}, 100b_{i,j}, 100d_{i,j}, and 100e_{i,j}, in any one of Aspects 1 to 4, preferably, the first interface (interfaces 17 and 17d) is configured to surround the sides of the light-emitting layers 11 and 11d and the sides of the P-type layers 12 and 12d, in addition to the sides of the first regions 101 and 101d.

According to the above configuration, the first interface (interfaces 17 and 17d) surrounds not only the sides of the first regions 101 and 101d, but also the sides of the light-emitting layers 11 and 11d and the sides of the P-type layers 12 and 12d. Thus, at the first interface (interfaces 17 and 17d), in addition to the light propagating in the direction toward the light-emitting layer 11 and the light propagating in the direction having an elevation angle from the light-emitting layers 11 and 11d toward the z-axis positive direction side, light propagating in a direction having an elevation angle from the light-emitting layers 11 and 11d toward the z-axis negative direction side may also be reflected in the direction toward the light emission surfaces 103 and 103d. Thus, in the micro-LED elements 100_{i,j}, 100a_{i,j}, 100b_{i,j}, 100d_{i,j}, and 100e_{i,j}, it is possible to more reliably suppress decrease of light emission efficiency in comparison to the micro-LED element in the related art, even if the size of the micro-LED element is reduced.

According to Aspect 6 of the present invention, in the micro-LED elements 100_{i,j}, 100a_{i,j}, 100b_{i,j}, 100c_{i,j}, 100d_{i,j}, and 100e_{i,j}, in any one of Aspects 1 to 5, preferably, in a case of being viewed from the P-side electrode layers 30, 30a, 30b, 30c, 30d, and 30e side in plan view, the P-side electrode layers 30, 30a, 30b, 30c, 30d, and 30e are formed in the regions covering the entirety of the light-emitting layers 11, 11c, and 11d.

According to the above configuration, regardless of the small area of the P-type layers 12, 12c, and 12d, it is possible to form the P-side electrode layers 30, 30a, 30b, 30c, 30d, and 30e having a wide area. Thus, the micro-LED elements 100_{i,j}, 100a_{i,j}, 100b_{i,j}, 100c_{i,j}, 100d_{i,j}, and 100e_{i,j}, are stably and firmly connected to the drive circuit-side P-electrodes 80 and 80d using the connection layers 70 and 70d. Thus, it is possible to reduce the frequency of occurrence of defects which may occur in the production step of the micro-LED elements 100_{i,j}, 100a_{i,j}, 100b_{i,j}, 100c_{i,j}, 100d_{i,j}, and 100e_{i,j}. Further, it is possible to reduce the damage on the light-emitting layers 11, 11c, and 11d, which may occur in the production step (in particular, second etching steps S17, S117, and S218), to improve the internal quantum efficiency, and to improve the light emission efficiency.

According to Aspect 7 of the present invention, in the micro-LED elements 100_{i,j}, 100a_{i,j}, 100b_{i,j}, 100c_{i,j}, 100d_{i,j}, and 100e_{i,j}, in Aspect 6, preferably, the surfaces of the P-side electrode layers 30, 30a, 30b, 30c, 30d, and 30e on the opposite side of the P-type layer are flat.

According to the above configuration, regardless of the small area of the P-type layers 12, 12c, and 12d, it is possible to form the P-side electrode layers 30, 30a, 30b, 30c, 30d, and 30e having a wide area and a flat surface. Thus, the micro-LED elements 100_{i,j}, 100a_{i,j}, 100b_{i,j}, 100c_{i,j}, 100d_{i,j}, and 100e_{i,j} are more stably and firmly connected to the drive circuit-side P-electrodes 80 and 80d using the connection layers 70 and 70d. Thus, it is possible to more reduce the frequency of occurrence of defects which may occur in the production step of the micro-LED elements 100_{i,j}, 100a_{i,j}, 100b_{i,j}, 100c_{i,j}, 100d_{i,j}, and 100e_{i,j}.

According to Aspect 8 of the present invention, in the micro-LED elements 100_{i,j}, 100a_{i,j}, 100b_{i,j}, 100c_{i,j}, and 100d_{i,j}, in Aspect 7, preferably, the buried layers 20, 20c, and 20d surrounding the first interface (interfaces 17, 17c, and 17d) are formed between the outer sides of the first regions 101, 101c, and 101d and the P-side electrode layers 30, 30a, 30b, 30c, and 30d. Preferably, the interface (lower end surfaces 201, 201c, and 201d) between the P-side electrode layers 30, 30a, 30b, 30c, and 30d and the buried layers 20, 20c, and 20d is parallel to the light-emitting layers 11, 11c, and 11d.

Since the interface (lower end surfaces 201, 201c, and 201d) between the P-side electrode layers 30, 30a, 30b, 30c, and 30d and the buried layers 20, 20c, and 20d is parallel to the light-emitting layers 11, 11c, and 11d, it is not necessary to flatten the surfaces of the P-side electrode layers 30, 30a, 30b, 30c, and 30d. Thus, even though the electrode layers are relatively thin, the electrode layers are parallel to the light-emitting layers 11, 11c, and 11d. As a result, in a case where the micro-LED elements 100_{i,j}, 100a_{i,j}, 100b_{i,j}, 100c_{i,j}, and 100d_{i,j} are mounted on the drive circuit substrates 90 and 90d, the surfaces of the drive circuit substrates 90 and 90d are automatically parallel to the light-emitting layers 11, 11c, and 11d. Accordingly, according to the above configuration, in a case where the micro-LED elements 100_{i,j}, 100a_{i,j}, 100b_{i,j}, 100c_{i,j}, and 100d_{i,j} are mounted on the drive circuit substrates 90 and 90d, it is not necessary to notice the inclination of the micro-LED elements 100_{i,j}, 100a_{i,j}, 100b_{i,j}, 100c_{i,j}, and 100d_{i,j} Thus, it is easy to perform a mounting operation.

According to Aspect 9 of the present invention, in the micro-LED elements 100_{i,j}, 100a_{i,j}, 100b_{i,j}, 100c_{i,j}, and 100e_{i,j}, in any one of Aspects 1 to 8, the configuration in which the N-side electrode layer (common N-side electrode layer 40) is stacked on the light emission surfaces 103, 103c, and 103d side may be employed.

According to the above configuration, in the micro-LED elements 100_{i,j}, 100a_{i,j}, 100b_{i,j}, 100c_{i,j}, and 100e_{i,j}, in comparison to the micro-LED element 100d_{i,j} according to Aspect 10 of the present invention described later, it is possible to increase the areas of the P-side electrode layer and the light-emitting layer. Thus, it is possible to easily produce the smaller micro-LED element.

According to Aspect 10 of the present invention, in the micro-LED element 100d_{i,j} in any one of Aspects 1 to 8, the configuration in which the nitride semiconductor layer 13d further includes the third interface (interface 18d) connecting the first interface (interface 17d) and the second interface (interface 19d), and the N-side electrode layer 40d is in contact with the second region 102d of the N-type layer 10d at the third interface (interface 18d) may be made.

According to the above configuration, it is not necessary to stack the N-side electrode layer on the light emission surfaces 103, 103c, and 103d as in the above-described micro-LED elements 100_{i,j}, 100a_{i,j}, 100b_{i,j}, 100c_{i,j}, and 100e_{i,j} according to Aspect 9 of the present invention. Thus, in the micro-LED element 100d_{i,j}, in comparison to the micro-LED elements 100_{i,j}, 100a_{i,j}, 100b_{i,j}, 100c_{i,j}, and 100e_{i,j}, it is possible to omit the common N-side electrode forming step in the production step of the image display element 200d. As a result, it is possible to simplify the production step, to reduce equipment investment, and to reduce production cost.

According to Aspect 11 of the present invention, preferably, the image display element 200 includes a plurality of the micro-LED elements 100_{i,j}, 100a_{i,j}, 100b_{i,j}, 100c_{i,j}, 100d_{i,j}, and 100e_{i,j} according to any one of Aspects 1 to 10, and the drive circuit substrates 90 and 90d on which the drive circuit configured to supply the drive current to each of the plurality of the micro-LED elements 100_{i,j}, 100a_{i,j}, 100b_{i,j}, 100c_{i,j}, 100d_{i,j}, and 100e_{i,j} Preferably, the plurality of the micro-LED elements 100_{i,j}, 100a_{i,j}, 100b_{i,j}, 100c_{i,j}, 100d_{i,j}, and 100e_{i,j} are stacked on the drive circuit substrates 90 and 90d in a two-dimensional array.

According to Aspect 12 of the present invention, the production methods S1 and S101 include the first deposition steps S11 and Sill of obtaining the nitride semiconductor layers 13, 13c, and 13d by depositing the N-type layers 10, 10c, and 10d, the light-emitting layers 11, 11c, and 11d, and the P-type layers 12, 12c, and 12d on the growth substrates 1 and 1d in this order, the first etching steps S12 and S112 of forming the first groove portion (groove portions 16, 16c, and 16d) and providing the first regions 101, 101c, and 101d having an etched side and the second regions 102, 102c, and 102d being the regions other than the first regions 101, 101c, and 101d, in the N-type layers 10, 10c, and 10d, by etching the portions of the nitride semiconductor layers 13, 13c, and 13d, the second deposition steps S13 and S113 of depositing the buried layers 20, 20c, and 20d on the first groove portion (groove portions 16, 16c, and 16d), the polishing steps S14 and S114 of polishing the surfaces of the buried layers 20, 20c, and 20d, the P-side electrode layer forming step S15 (electrode layer forming step S116) of forming the P-side electrode layer on the surface polished in the polishing steps S14 and S114, and the second etching steps S16 and S117 of forming the second groove portion (groove portions 50 and 50d) exposing the portions of the growth substrates 1 and 1d by etching the buried layers 20, 20c, and 20d and the second regions 102, 102c, and 102d.

In the first etching steps S12 and S112, the first groove portion (groove portions 16, 16c, and 16d) are formed such that the angle θ₁ between the first interface (interfaces 17, 17c, and 17d) surrounding at least the sides of the first regions 101, 101c, and 101d and the light-emitting layers 11, 11c, and 11d in the nitride semiconductor layers 13, 13c, and 13d is the prescribed first angle (for example, 45 degrees) at which light propagating in the direction toward the light-emitting layers 11, 11c, and 11d is reflected in the direction toward the light emission surfaces 103, 103c, and 103d. In the second etching steps S16 and S117, the second groove portion (groove portions 50 and 50d) is formed such that the angle θ₂ between the second interface (interfaces 19, 19c, and 19d) surrounding the sides of the second regions 102, 102c, and 102d and the light-emitting layers 11, 11c, and 11d in the nitride semiconductor layers 13, 13c, and 13d is the prescribed second angle larger than the first angle (for example, 45 degrees).

According to Aspect 13 of the present invention, the production method S201 includes the first deposition step S211 of obtaining the nitride semiconductor layer 13 by depositing the N-type layer 10, the light-emitting layer 11, and the P-type layer 12 on the growth substrate 1 in this order, the first etching step S212 of forming the first groove portion (groove portion 16) by etching the portion of the nitride semiconductor layer 13, and providing the first region 101 having an etched side and the second region 102 being the region other than the first region 101 in the N-type layer 10, the second deposition step S213 of depositing the protective layer 20e on the nitride semiconductor layer 13, the contact hole forming step S214 of forming the contact hole 21e in the protective layer 20e to expose the portion of the first region 101, the P-side electrode layer forming step S215 of forming the P-side electrode layer 30e to cover the contact hole 21e, and the second etching step S218 of forming the second groove portion (groove portion 50e) exposing the portion of the growth substrate 1, by etching the protective layer 20e and the second region 102.

In the first etching step S212, the first groove portion (groove portion 16) is formed such that the angle θ₁ between the first interface (interface 17) surrounding at least the side of the first region 101 and the light-emitting layer 11 in the nitride semiconductor layer 13 is the prescribed first angle (for example, 45 degrees) at which the light propagating in the direction toward the light-emitting layer 11 is reflected in the direction toward the light emission surface 103. In the second etching step S218, the second groove portion (groove portion 50e) is formed such that the angle θ₂ between the second interface (interface 19) surrounding the side of the second region 102 and the light-emitting layer 11 in the nitride semiconductor layer 13 is the prescribed second angle larger than the first angle (for example, 45 degrees).

According to the above configuration, all of the image display element 200, the production method S1, the production method S101, and the production method S201 exhibit the effects similar to the effects of the micro-LED elements 100_{i,j}, 100a_{i,j}, 100b_{i,j}, 100c_{i,j}, 100d_{i,j}, and 100e_{i,j} according to Aspect 1 of the present invention. That is, even in a case where the sizes of the micro-LED elements 100_{i,j}, 100a_{i,j}, 100b_{i,j}, 100c_{i,j}, 100d_{i,j}, and 100e_{i,j} are reduced, in the image display element 200, it is possible to suppress decrease of light emission efficiency. With the production method S1, the production method S101, and the production method S201, it is possible to produce the micro-LED elements 100_{i,j}, 100a_{i,j}, 100b_{i,j}, 100c_{i,j}, 100d_{i,j}, and 100e_{i,j} capable of suppressing the decrease in the light emission efficiency even in a case where the size thereof is reduced.

The present invention is not limited to the above embodiments, and various modifications may be made within the scope described in the claims, and embodiments obtained by appropriately combining the technical means disclosed in different embodiments are also included in the technical scope of the present invention. Further, new technical features can be formed by combining the technical means disclosed in the embodiments.

1. A micro-LED element comprising:
a nitride semiconductor layer in which an N-type layer, a light-emitting layer, and a P-type layer are stacked in this order when viewed from a light emission surface side; and
a P-side electrode layer formed on the P-type layer side,
wherein the N-type layer includes a first region in contact with the light-emitting layer and a second region including the light emission surface,
an angle between a first interface surrounding at least a side of the first region in the nitride semiconductor layer and the light-emitting layer is a prescribed first angle at which light propagating in a direction along the light-emitting layer is reflected in a direction toward the light emission surface,
an angle between a second interface surrounding a side of the second region in the nitride semiconductor layer and the light-emitting layer is a prescribed second angle larger than the first angle, and
the first interface is surrounded by a transparent buried layer, the second interface is not covered by the buried layer, and another side surface of the buried layer forms a flat surface continuously connected with the second interface in an entire circumference when viewed from the light emission surface side.

2-5. (canceled)

6. A micro-LED element comprising:
a nitride semiconductor layer in which an N-type layer, a light-emitting layer, and a P-type layer are stacked in this order when viewed from a light emission surface side; and
a P-side electrode layer formed on the P-type layer side,
wherein the N-type layer includes a first region in contact with the light-emitting layer and a second region including the light emission surface,
an angle between a first interface surrounding at least a side of the first region in the nitride semiconductor layer and the light-emitting layer is a prescribed first angle at which light portaging in a direction along the light-emitting layer is reflected in a direction toward the light emission surface,
an angle between a second interface surrounding a side of the second region in the nitride semiconductor layer and the light-emitting layer is a prescribed second angle larger than the first angle, and
in a case of being viewed from the P-side electrode layer side in plan view, the P-side electrode layer is formed in a region covering an entirety of the light-emitting layer.

7. The micro-LED element according to claim 6, wherein
a surface of the P-side electrode layer on an opposite side of the P-type layer is flat.

8. The micro-LED element according to claim 7, wherein
a buried layer surrounding the first interface is formed between an outer side of the first region and the P-side electrode layer, and
an interface between the P-side electrode layer and the buried layer is parallel to the light-emitting layer.

9. (canceled)

10. The micro-LED element according to claim 1, wherein
the nitride semiconductor layer further includes a third interface connecting the first interface and the second interface, and
an N-side electrode layer is in contact with the second region of the N-type layer at the third interface.

11-13. (canceled)

14. The micro-LED element according to claim 6, wherein
the first angle is an angle in a predetermined range centering on 45 degrees.

15. The micro-LED element according to claim 6, wherein
the first angle is an angle in a range of 35 degrees to 55 degrees.

16. The micro-LED element according to claim 6, wherein
a thickness of the first region is thicker than a thickness of the P-type layer.

17. The micro-LED element according to claim 6, wherein
the first interface surrounds a side of the light-emitting layer and a side of the P-type layer in addition to the side of the first region.

18. The micro-LED element according to claim 6, wherein
an N-side electrode layer is stacked on the light emission surface.

19. An image display element comprising:
a plurality of micro-LED elements; and
a drive circuit substrate in which a drive circuit configured to supply a drive current to each of the plurality of micro-LED elements is formed,
wherein the plurality of micro-LED elements are stacked on the drive circuit substrate in a two-dimensional array,
each of the plurality of micro-LED elements comprising:
a nitride semiconductor layer in which an N-type layer, a light-emitting layer, and a P-type layer are stacked in this order when viewed from a light emission surface side; and
a P-side electrode layer formed on the P-type layer side,
wherein the N-type layer includes a first region in contact with the light-emitting layer and a second region including the light emission surface,
an angle between a first interface surrounding at least a side of the first region in the nitride semiconductor layer and the light-emitting layer is a prescribed first angle at which light propagating in a direction along the light-emitting layer is reflected in a direction toward the light emission surface,
an angle between a second interface surrounding a side of the second region in the nitride semiconductor layer and the light-emitting layer is a prescribed second angle larger than the first angle, and
an N-side electrode layer is stacked on the light emission surface.

20. The image display element according to claim 19, wherein
gaps between the plurality of micro-LED elements are filled with a high reflective material or a high light-absorbing material.

21. The image display element according to claim 19, wherein
in a case of being viewed from the P-side electrode layer side in plan view, the P-side electrode layer is formed in a region covering an entirety of the light-emitting layer.

22. The image display element according to claim 19, wherein
an entire circumference of the first interface is transparent to visible light and covered by a protection film having a refractive index smaller than a refractive index of the nitride semiconductor layer.

23. The image display element according to claim 22, wherein
an outer side of the protection film is surrounded in an entire circumference by the P-side electrode layer.

24. The micro-LED element according to claim 6, wherein
an entire circumference of the first interface is transparent to visible light and covered by a protection film having a refractive index smaller than a refractive index of the nitride semiconductor layer, and an outer side of the protection film is surrounded in an entire circumference by the P-side electrode layer.

25. The micro-LED element according to claim 1, wherein
the first angle is an angle in a range of 35 degrees to 55 degrees.

26. The micro-LED element according to claim 1, wherein
a thickness of the first region is thicker than a thickness of the P-type layer.

27. The micro-LED element according to claim 1, wherein
the first interface surrounds a side of the light-emitting layer and a side of the P-type layer in addition to the side of the first region.

28. The micro-LED element according to claim 1, wherein
an N-side electrode layer is stacked on the light emission surface.
